(19) United States
(12) Patent Application Publication
(10) Pub. No.: US 2026/0107446 A1
(43) Pub. Date: Apr. 16, 2026

(54) SEMICONDUCTOR MEMORY DEVICE INCLUDING A VERTICAL CHANNEL TRANSISTOR

(71) Applicant: SAMSUNG ELECTRONICS CO., LTD., SUWON-SI (KR)

(72) Inventors: Tae Hyuk KIM, Suwon-si (KR); Suk Lae KIM, Suwon-si (KR); Taek Yong KIM, Suwon-si (KR); Tae Jin PARK, Suwon-si (KR); Hyeon-Kyu LEE, Suwon-si (KR)

(21) Appl. No.: 19/261,004

(22) Filed: Jul. 7, 2025

(30) Foreign Application Priority Data
Oct. 11, 2024 (KR) 10-2024-0138701

(51) Int. Cl. H10B 12/00

(52) U.S. Cl. CPC H10B 12/482; H10B 12/315; H10B 12/488

(57) ABSTRACT

A semiconductor memory device includes: a bit line extending in a first direction on a substrate; an active pattern disposed on the bit line, and including a first and second sidewalls opposite to each other in the first direction, and a first and second surfaces opposite to each other in a vertical direction that intersects the first direction; a word line disposed on the first sidewall of the active pattern, and extending in a second direction crossing the first direction; a back gate electrode disposed on the second sidewall of the active pattern; a data storage pattern disposed on the active pattern; a gate isolation pattern disposed on the word line; a back gate isolation pattern disposed on the back gate electrode; and a landing pad disposed between the gate isolation pattern and the back gate isolation pattern.

### CROSS-REFERENCE TO RELATED APPLICATION

This application claims priority under 35 USC § 119 to Korean Patent Application No. 10-2024-0138701 filed on Oct. 11, 2024 in the Korean Intellectual Property Office, the disclosure of which is incorporated by reference herein in its entirety.

### TECHNICAL FIELD

Embodiments of the present inventive concept relate to a semiconductor memory device, and more particularly, to a semiconductor memory device including a vertical channel transistor (VCT).

### DISCUSSION OF THE RELATED ART

To satisfy consumer demands for superior performance of memory devices at inexpensive prices, it is desired to increase the integration density of semiconductor memory devices. In a semiconductor memory device, since the integration density of the semiconductor memory device is an important factor in determining the price of a product, an increased integration density of a semiconductor memory device is very desirable.

In the case of a two-dimensional or planar semiconductor memory device, the integration density is mainly determined by the area occupied by a unit memory cell, and thus, the integration density is greatly influenced by the precision of fine pattern formation technology. However, since extremely high-priced equipment is required for the miniaturization of patterns, the integration density of the two-dimensional semiconductor memory device has been increased but remains insufficient to meet the desired level of integration due to technological and cost limitations. Accordingly, semiconductor memory devices including vertical channel transistors, in which a channel extends in a vertical direction, have been under development.

### SUMMARY

According to embodiments of the present inventive concept, a semiconductor memory device includes: a bit line extending in a first direction on a substrate; an active pattern disposed on the bit line, and including a first sidewall and a second sidewall opposite to each other in the first direction, and a first surface and a second surface opposite to each other in a vertical direction that intersects the first direction, wherein the first surface of the active pattern is connected to the bit line; a word line disposed on the first sidewall of the active pattern, and extending in a second direction crossing the first direction; a back gate electrode disposed on the second sidewall of the active pattern, and extending in the second direction; a data storage pattern disposed on the active pattern; a gate isolation pattern disposed between the bit line and the data storage pattern, and disposed on the word line; a back gate isolation pattern disposed between the back gate electrode and the data storage pattern, and disposed on the back gate electrode; and a landing pad disposed between the gate isolation pattern and the back gate isolation pattern, and in contact with the data storage pattern.

According to embodiments of the present inventive concept, a semiconductor memory device includes: a bit line extending in a first direction on a substrate; a back gate electrode disposed on the bit line, and extending in a second direction crossing the first direction, wherein the back gate electrode includes a first sidewall and a second sidewall opposite to each other in the first direction, and a first surface and a second surface opposite to each other in a vertical direction, wherein the first surface of the back gate electrode faces the bit line; a first word line disposed on the first sidewall of the back gate electrode, and extending in the second direction; a second word line disposed on the second sidewall of the back gate electrode, and extending in the second direction; a first active pattern disposed between the back gate electrode and the first word line; a second active pattern disposed between the back gate electrode and the second word line; landing pads respectively disposed on the first active pattern and the second active pattern; data storage patterns disposed on the second surface of the back gate electrode, and respectively connected to the landing pads; and a back gate isolation pattern disposed between the back gate electrode and the data storage patterns, and disposed on the second surface of the back gate electrode, wherein each of the landing pads includes an upper surface facing the data storage patterns. The back gate isolation pattern includes an upper surface facing the data storage patterns, and the upper surface of each of the landing pads is coplanar with the upper surface of the back gate isolation pattern.

According to embodiments of the present inventive concept, a semiconductor memory device includes: a bit line extending in a first direction on a substrate; a shielding conductive pattern disposed on the substrate, and including a plurality of shielding conductive line patterns adjacent to the bit line and extending in the first direction; a back gate electrode disposed on the bit line and the shielding conductive pattern, and extending in a second direction; a word line disposed on the bit line and the shielding conductive pattern, and spaced apart from the back gate electrode in the first direction, wherein the word line extends in the second direction; a data storage pattern disposed on the word line and the back gate electrode; an active pattern disposed between the bit line and the data storage pattern, and connected to the bit line and the data storage pattern, wherein the active pattern includes a sidewall extending in a vertical direction; a landing pad disposed between the active pattern and the data storage pattern, and including a sidewall extending in the vertical direction; and a gate insulating pattern disposed between the word line and the active pattern, and extending along the sidewall of the active pattern and the sidewall of the landing pad.

According to embodiments of the present inventive concept, a method of manufacturing a semiconductor memory device includes: providing a substrate including a first sub-substrate, a buried insulating layer, and an active layer, wherein the active layer is formed on the buried insulating layer; forming a mask pattern on the active layer, wherein the mask pattern includes a plurality of line-shaped openings extending in a first direction; etching the active layer using the mask pattern as an etching mask to form a plurality of back gate trenches extending in the first direction; forming a back gate insulating pattern along sidewalls and a lower surface of each of the back gate trenches; depositing a conductive material in the back gate trenches and etching back the conductive material to form a plurality of back gate electrodes extending in the first direction; filling the remaining portions of the back gate trenches with a back gate isolation pattern; forming a spacer film along an upper surface of the back gate isolation pattern and the sidewalls of the back gate insulating pattern; performing an etching process on the spacer film to form a pair of spacer patterns on sides of the back gate insulating pattern; using the spacer patterns as an etching mask to etch the active layer to form first and second active patterns that are spaced apart from each other; forming a gate insulating pattern along sidewalls of the first and second active patterns and the upper surface of the back gate isolation pattern; depositing and patterning a conductive material on the gate insulating pattern to form first and second word lines; forming a contact pattern and a landing pad between the back gate isolation pattern and the gate insulating pattern, and on the first and second active patterns; forming a bit line on the first and second active patterns; and forming data storage patterns on the landing pad.

In embodiments of the present inventive concept, the method further includes forming a gate isolation pattern on the first and second word lines.

In embodiments of the present inventive concept, the method further includes forming active pattern recesses by etching portions of the first and second active patterns, wherein the contact pattern and the landing pad are formed in the active pattern recesses.

### BRIEF DESCRIPTION OF THE DRAWINGS

The above and other aspects and features of the present inventive concept will become more apparent by describing in detail example embodiments thereof with reference to the attached drawings, in which:

FIG. 1 is a layout diagram illustrating a semiconductor memory device according to embodiments of the present inventive concept.

FIG. 2 is a cross-sectional view taken along lines A-A and B-B of FIG. 1.

FIG. 3 is a cross-sectional view taken along lines C-C and D-D of FIG. 1.

FIG. 4 is an enlarged view of part P of FIG. 2.

FIGS. 5 and 6 are enlarged views of the landing pad of FIG. 4.

FIGS. 7, 8, and 9 are diagrams each illustrating a semiconductor memory device according to embodiments of the present inventive concept.

FIGS. 10 and 11 are diagrams illustrating a semiconductor memory device according to embodiments of the present inventive concept.

FIGS. 12 and 13 are diagrams illustrating a semiconductor memory device according to embodiments of the present inventive concept.

FIGS. 14 and 15 are diagrams illustrating a semiconductor memory device according to embodiments of the present inventive concept.

FIGS. 16 and 17 are diagrams illustrating a semiconductor memory device according to embodiments of the present inventive concept.

FIGS. 18 and 19 are diagrams illustrating a semiconductor memory device according to embodiments of the present inventive concept.

FIGS. 20 and 21 are diagrams each illustrating a semiconductor memory device according to embodiments of the present inventive concept.

FIGS. 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, and 56 are views illustrating intermediate steps of a method for fabricating a semiconductor memory device according to embodiments of the present inventive concept.

### DETAILED DESCRIPTION OF THE EMBODIMENTS

Embodiments of the present inventive concept will be described more fully hereinafter with reference to the accompanying drawings. It is to be understood that the present inventive may, however, be embodied in different forms and thus should not be construed as being limited to the embodiments set forth herein. In the drawings, like reference numerals may refer to like elements, and thus repetitive descriptions may be omitted.

As used herein, the singular forms “a”, “an”, and “the” are intended to include the plural forms as well, unless the context clearly indicates otherwise.

It is to be understood that singular expressions include plural expressions unless the context clearly dictates otherwise.

Embodiments of the present inventive concept relate to a semiconductor memory device that incorporates vertical channel transistors (VCTs) to increase integration density and electrical performance. Unlike conventional planar memory devices, which face limitations in miniaturization due to high fabrication costs and lithographic constraints, the proposed design utilizes a vertical structure for the transistor channels, allowing for greater scalability. This approach may increase packing efficiency.

According to embodiments of the present inventive concept, transistor control and leakage current reduction may be provided. The semiconductor memory device, according to embodiments of the present inventive concept, may include a bit line, an active pattern, and word lines. Additionally, the device may include a gate isolation pattern and a back gate isolation pattern, ensuring proper electrical separation and increased stability. The integration of these structures may provide control over threshold voltages and leakage currents, leading to increased power efficiency and performance reliability.

According to embodiments of the present inventive concept, the device may further include landing pads and contact patterns vertically stacked on active patterns of the memory device. The memory device may further include a bit line, which is connected to the active patterns, and shielding conductive patterns disposed on the bit line. Accordingly, signal integrity may be increased and noise interference may be reduced. The device may also include gate insulating patterns and back gate insulating patterns, which provide additional electrical isolation.

Furthermore, the method of manufacturing the semiconductor memory device allows for the self-aligned formation of certain components, such as the landing pads and the contact patterns, thereby reducing the number of processing steps. This not only simplifies manufacturing but also lowers production costs. The approach may enable the formation of highly integrated semiconductor memory devices with minimal leakage and enhanced read/write characteristics.

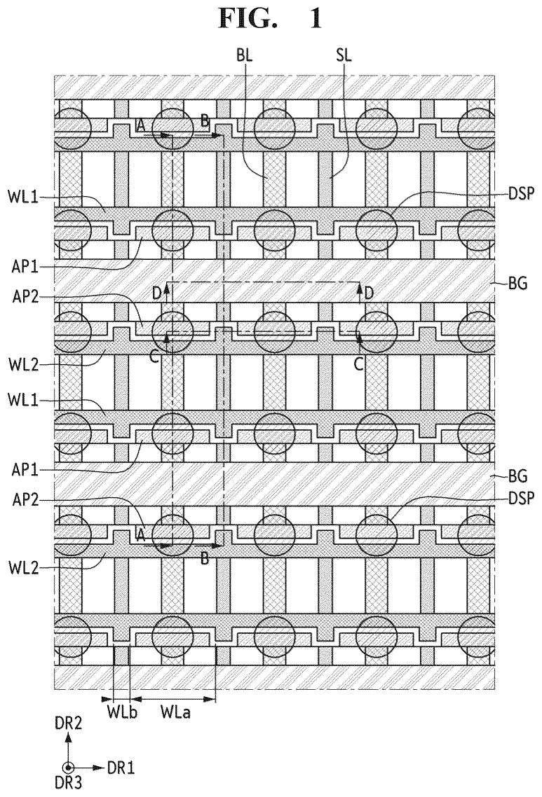

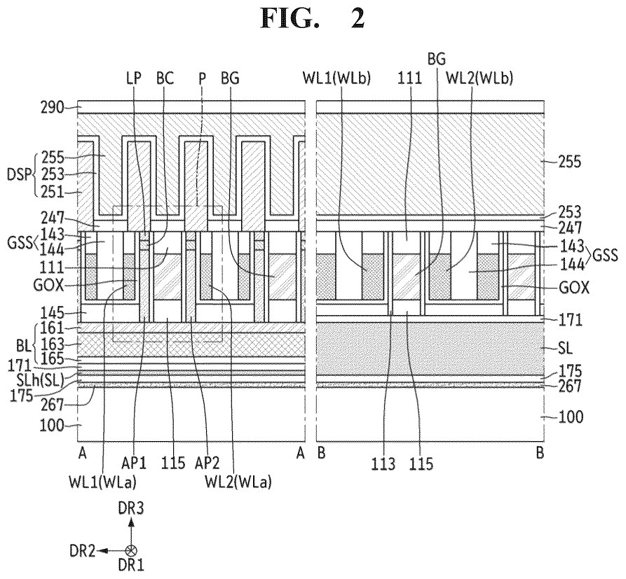

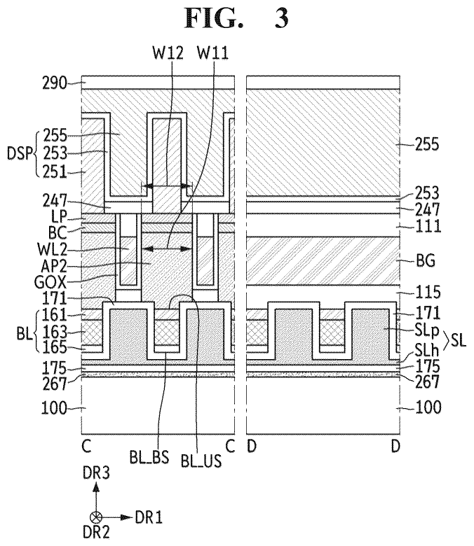

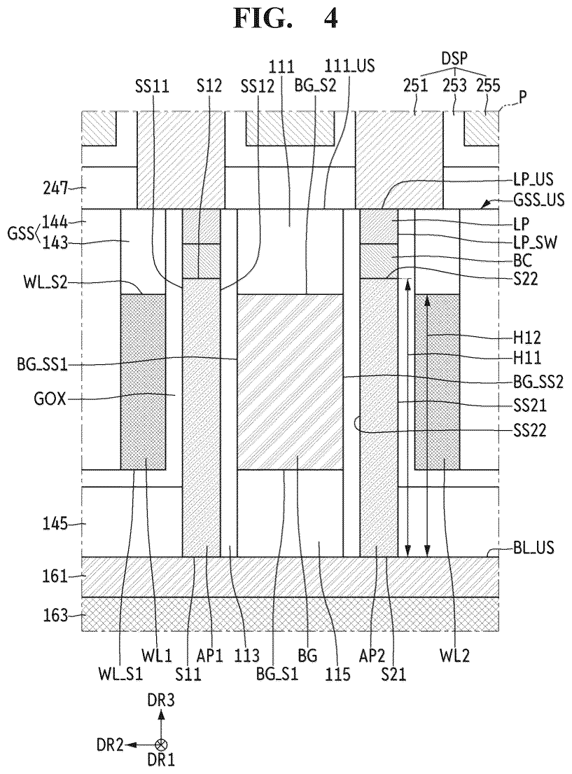

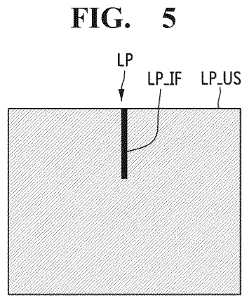

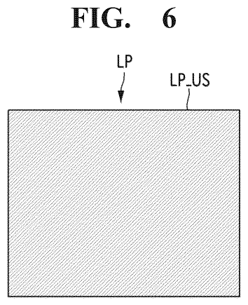

FIG. 1 is a layout diagram illustrating a semiconductor memory device according to embodiments of the present inventive concept. FIG. 2 is a cross-sectional view taken along lines A-A and B-B of FIG. 1. FIG. 3 is a cross-sectional view taken along lines C-C and D-D of FIG. 1. FIG. 4 is an enlarged view of part P of FIG. 2. FIGS. 5 and 6 are enlarged views of the landing pad of FIG. 4.

The semiconductor memory device, according to embodiments of the present inventive concept, may include memory cells including a vertical channel transistor (VCT).

Referring to FIGS. 1 to 6, the semiconductor memory device according to embodiments of the present inventive concept may include bit lines BL, first word lines WL1, second word lines WL2, back gate electrodes BG, a shielding conductive pattern SL, first active patterns AP1, second active patterns AP2, and data storage patterns DSP.

A substrate 100 may be a silicon substrate, or may include other materials such as silicon germanium, indium antimonide, lead tellurium compound, indium arsenide, indium phosphide, gallium arsenide, or gallium antimonide, but the present inventive concept is not limited thereto.

The substrate 100 may include a cell array region and a peripheral circuit region. In the cell array region, the data storage pattern DSP is disposed, and the peripheral circuit region is disposed adjacent to the cell array region.

A bonding insulating film 267 may be disposed on the substrate 100. The bonding insulating film 267 may be used to bond wafers to each other. For example, the bonding insulating film 267 may include silicon carbonitride. For another example, the bonding insulating film 267 may include silicon oxide.

A shielding structure 171, SL, and 175 may be disposed above the substrate 100. For example, the shielding structure 171, SL, and 175 may be disposed on the bonding insulating film 267.

The shielding structure 171, SL, and 175 may include the shielding conductive pattern SL and shielding insulating films 171 and 175. For example, the shielding insulating films 171 and 175 may include a shielding insulating liner 171 and a shielding insulating capping film 175.

The shielding conductive pattern SL may include a shielding conductive plate SLh and a plurality of shielding conductive line patterns SLp. The shielding conductive plate SLh may have a shape of a flat plate.

Each of the shielding conductive line patterns SLp may extend in a second direction DR2. The shielding conductive line patterns SLp may be adjacent to each other in a first direction DR1. The shielding conductive line pattern SLp may protrude from the shielding conductive plate SLh in a third direction DR3. The shielding conductive line pattern SLp is directly connected to the shielding conductive plate SLh. For example, the shielding conductive line patterns SLp may be connected to each other through the shielding conductive plate SLh. For example, the shielding conductive line pattern SLp and the shielding conductive plate SLh may be integrally connected to each other.

For example, the first direction DR1 and the second direction DR2 may be horizontal directions that are parallel to the substrate 100. The third direction DR3 may be a vertical direction perpendicular to the substrate 100 and the first and second directions DR1 and DR2.

The shielding conductive plate SLh and each of the shielding conductive line patterns SLp may extend from the cell array region to the peripheral circuit region. A portion of the shielding conductive pattern SL may be disposed on the peripheral circuit region, but the present inventive concept is not limited thereto.

The shielding conductive pattern SL includes a conductive material. The shielding conductive pattern SL may include, for example, at least one of conductive metal nitride, conductive metal silicon nitride, metal carbonitride, conductive metal silicide, conductive metal oxide, conductive metal oxynitride, a 2D material, or metal.

The shielding insulating capping film 175 may be disposed on the substrate 100. For example, the shielding insulating capping film 175 may be disposed between the substrate 100 and the shielding conductive pattern SL.

For example, the shielding insulating capping film 175 may be in contact with the shielding conductive pattern SL. In the semiconductor memory device according to embodiments of the present inventive concept, the shielding insulating capping film 175 may be in contact with the shielding conductive plate SLh.

The shielding insulating liner 171 may be disposed on the shielding conductive pattern SL. The shielding insulating liner 171 may be disposed between the bit line BL and the substrate 100. The shielding insulating liner 171 may extend along the profiles of the shielding conductive plate SLh and the shielding conductive line patterns SLp.

Each of the shielding insulating liner 171 and the shielding insulating capping film 175 may be made of an insulating material. When the shielding insulating liner 171 and the shielding insulating capping film 175 include the same material as each other, an interface between the shielding insulating liner 171 and the shielding insulating capping film 175 may not be apparent.

Since the shielding structures 171, SL, and 175 are disposed between neighboring bit lines BL of the bit lines BL in the first direction DR1, coupling noise between the bit lines BL may be reduced.

In an embodiment of the present inventive concept, the semiconductor memory device does not include the shielding conductive pattern SL.

The bit lines BL may be disposed on the substrate 100. For example, the bit lines BL may be disposed on the bonding insulating film 267.

The bit line BL may extend in the second direction DR2. Adjacent bit lines BL may be spaced apart from each other in the first direction DR1. Each of the bit line BL includes a long sidewall extending in the second direction DR2 and a short sidewall extending in the first direction DR1.

The bit line BL may be disposed above the shielding conductive pattern SL. The bit line BL may be disposed above the shielding conductive plate SLh.

The bit line BL may be disposed adjacent to the shielding conductive line pattern SLp. The bit line BL may be disposed adjacent to the shielding conductive line pattern SLp in the first direction DR1. In other words, the shielding conductive line pattern SLp may extend in the second direction DR2 along the long sidewall of the bit line BL.

The bit line BL may be disposed between neighboring shielding conductive line patterns SLp of the shielding conductive line patterns SLp in the first direction DR1. The bit line BL may be disposed on the shielding insulating liner 171. For example, the shielding insulating liner 171 may be in contact with the bit line BL.

For example, each of the bit lines BL may extend from the cell array region to the peripheral circuit region. A portion of each of the bit lines BL may be disposed on the peripheral circuit region.

The bit line BL may include an upper surface BL_US and a lower surface BL_BS which are opposite to each other in the third direction DR3. The upper surface BL_US of the bit line BL may face the first active patterns AP1 and the second active patterns AP2 to be described later.

In a semiconductor memory device according to embodiments of the present inventive, the shielding conductive pattern SL may be disposed on the lower surface BL_BS of the bit line BL. For example, the shielding conductive plate SLh may be disposed on the lower surface BL_BS of the bit line BL.

Each of the bit lines BL may include a semiconductor pattern 161, a metal pattern 163, and a bit line mask pattern 165 that are sequentially stacked on the substrate 100. For example, the bit line BL may include one of the semiconductor pattern 161 or the metal pattern 163. As another example, the bit line BL might not include the bit line mask pattern 165.

The bit line BL may include a conductive bit line. The conductive bit line includes a film made of a conductive material in the bit line BL. The conductive bit line may include the semiconductor pattern 161 and the metal pattern 163.

The semiconductor pattern 161 may include a conductive semiconductor material. The conductive semiconductor material may be, for example, a semiconductor material doped with impurities. The semiconductor pattern 161 may include at least one of polysilicon, polysilicon germanium, polygermanium, amorphous silicon, amorphous silicon germanium, or amorphous germanium.

The metal pattern 163 may include a conductive material including metal. The metal pattern 163 may include, for example, at least one of conductive metal nitride, conductive metal silicon nitride, metal carbonitride, conductive metal silicide, conductive metal oxide, conductive metal oxynitride, a 2D material, or metal. In the semiconductor memory device according to embodiments of the present inventive concept, the 2D material may be a metallic material and/or a semiconductor material. The 2D material may include a 2D allotrope or a 2D compound. For example, it may include at least one of graphene, molybdenum disulfide (MoS₂), molybdenum diselenide (MoSe₂), tungsten diselenide (WSe₂), or tungsten disulfide (WS₂), but the present inventive concept is not limited thereto. For example, since the above-mentioned 2D materials are merely examples, the 2D materials that may be included in the semiconductor memory device of the present inventive concept are not limited thereto.

The bit line mask pattern 165 may include an insulating material. The bit line mask pattern 165 may include, for example, silicon nitride, silicon oxynitride, or the like, but the present is not limited thereto.

The first active patterns AP1 and the second active patterns AP2 may be disposed on each bit line BL. The first active patterns AP1 and the second active patterns AP2 may be disposed between the bit lines BL and the data storage patterns DSP. For example, the data storage patterns DSP may be disposed on the first active patterns AP1 and the second active patterns AP2. The first active patterns AP1 and the second active patterns AP2 may be alternately disposed along the second direction DR2.

The first active patterns AP1 may be spaced apart from each other in the first direction DR1. The first active patterns AP1 may be spaced apart from each other at regular intervals. The second active patterns AP2 may be spaced apart from each other in the first direction DR1. The second active patterns AP2 may be spaced apart from each other at regular intervals. The first active pattern AP1 may be spaced apart from the second active pattern AP2 in the second direction DR2. The first active patterns AP1 and the second active patterns AP2 may be two-dimensionally arranged along the first direction DR1 and the second direction DR2 that intersect each other.

Each of the first active pattern AP1 and the second active pattern AP2 may be a channel region. For example, each of the first active pattern AP1 and the second active pattern AP2 may be made of a single crystal semiconductor material. In one example, each of the first active pattern AP1 and the second active pattern AP2 may be made of single crystal silicon. Each of the first active pattern AP1 and the second active pattern AP2 may be a silicon active pattern.

Each of the first active pattern AP1 and the second active pattern AP2 may have a length in the first direction DR1, a width in the second direction DR2, and a height in the third direction DR3. Each of the first active pattern AP1 and the second active pattern AP2 may have a substantially uniform width.

The width of the first active pattern AP1 and the width of the second active pattern AP2 may be within a range of a few nm to tens of nm. For example, each of the width of the first active pattern AP1 and the width of the second active pattern AP2 may be about 1 nm to about 30 nm, but the present inventive concept is not limited thereto. As another example, each of the width of the first active pattern AP1 and the width of the second active pattern AP2 may be about 1 nm to about 10 nm, but the present inventive concept is not limited thereto. The length of each of the first and second active patterns AP1 and AP2 may be greater than the line width of the bit line BL. For example, the length of each of the first and second active patterns AP1 and AP2 may be greater than the width of the bit line BL in the first direction DR1.

In FIG. 4, the first active pattern AP1 includes a first surface S11 and a second surface S12, which are opposite to each other in the third direction DR3. The second active pattern AP2 includes a first surface S21 and a second surface S22, which are opposite to each other in the third direction DR3.

The first surface S11 of the first active pattern AP1 and the first surface S21 of the second active pattern AP2 may face the bit line BL. The first surface S11 of the first active pattern AP1 and the first surface S21 of the second active pattern AP2 are connected to the bit line BL. For example, the first surface S11 of the first active pattern AP1 and the first surface S21 of the second active pattern AP2 may be connected to the semiconductor pattern 161 of the bit line BL. For example, if the semiconductor pattern 161 is omitted, the first surface S11 of the first active pattern AP1 and the first surface S21 of the second active pattern AP2 may be connected to the metal pattern 163. The second surface S12 of the first active pattern AP1 and the second surface S22 of the second active pattern AP2 may be connected to landing pads LP.

The second surface S12 of the first active pattern AP1 and the second surface S22 of the second active pattern AP2 may face the landing pad LP. The second surface S12 of the first active pattern AP1 and the second surface S22 of the second active pattern AP2 may each be connected to the data storage pattern DSP.

The first active pattern AP1 includes a first sidewall SS11 and a second sidewall SS12 which are opposite to each other in the second direction DR2. The second active pattern AP2 includes a first sidewall SS21 and a second sidewall SS22 which are opposite to each other in the second direction DR2. The second sidewall SS12 of the first active pattern AP1 may face the second sidewall SS22 of the second active pattern AP2. Each of the first sidewall SS11 of the first active pattern AP1, the second sidewall SS12 of the first active pattern AP1, the first sidewall SS21 of the second active pattern AP2, and the second sidewall SS22 of the second active pattern AP2 may extend in the third direction DR3.

The first sidewall SS11 of the first active pattern AP1 may be adjacent to the first word line WL1. The first sidewall SS21 of the second active pattern AP2 may be adjacent to the second word line WL2.

As an example, each of the first active pattern AP1 and the second active pattern AP2 may include a first dopant portion and a second dopant portion. The first dopant may be adjacent to a corresponding bit line BL of the bit lines BL, and the second dopant portion may be adjacent to a contact pattern BC. Each of the first active pattern AP1 and the second active pattern AP2 may include a channel portion between the first dopant portion and the second dopant portion. The first dopant portion and the second dopant portion are regions of the first active pattern AP1 and the second active pattern AP2 formed by doping. In an embodiment of the present inventive concept, each of the first active pattern AP1 and the second active pattern AP2 might not include at least one of the first dopant portion or the second dopant portion.

During the operation of the semiconductor memory device, the channel portions of the first and second active patterns AP1 and AP2 may be controlled by the first and second word lines WL1 and WL2 and the back gate electrodes BG. Since the first and second active patterns AP1 and AP2 are made of a single crystal semiconductor material, the leakage current characteristics of the semiconductor memory device may be improved.

The back gate electrodes BG may be disposed above the bit line BL and the shielding conductive pattern SL. The back gate electrodes BG may be spaced apart from each other in the second direction DR2. The back gate electrodes BG may be spaced apart from each other at regular intervals. Each of the back gate electrodes BG may extend in the first direction DR1 across the bit line BL.

Each of the back gate electrodes BG may be disposed between the first active pattern AP1 and the second active pattern AP2, which are adjacent to each other in the second direction DR2. The back gate electrode BG may include a first sidewall BG_SS1 and a second sidewall BG_SS2 which are opposite to each other in the second direction DR2. The first active patterns AP1 may be disposed on the first sidewall BG_SS1 of each back gate electrode BG, and the second active patterns AP2 may be disposed on the second sidewall BG_SS2 of each back gate electrode BG. Each of the back gate electrodes BG may be disposed between the second sidewall SS12 of the first active pattern AP1 and the second sidewall SS22 of the second active pattern AP2. The height of the back gate electrode BG in the third direction DR3 may be smaller than the heights of the first and second active patterns AP1 and AP2.

The first active pattern AP1 may be disposed between the first word line WL1 and the back gate electrode BG. The second active pattern AP2 may be disposed between the second word line WL2 and the back gate electrode BG. A pair of the first word line WL1 and the second word line WL2 may be disposed between a pair of neighboring back gate electrodes BG of the back gate electrodes BG in the second direction DR2.

The back gate electrode BG may include a first surface BG_S1 and a second surface BG_S2 opposite to each other in the third direction DR3. The first surface BG_S1 of the back gate electrode BG is closer to the bit line BL than the second surface BG_S2 of the back gate electrode BG. The first surface BG_S1 of the back gate electrode BG may face the bit line BL.

The back gate electrode BG may include a conductive material, and may include, for example, at least one of a conductive semiconductor material, conductive metal nitride, conductive metal silicon nitride, metal carbonitride, conductive metal silicide, conductive metal oxide, conductive metal oxynitride, a 2D material, or metal. Although the back gate electrode BG is depicted as a single film, it is merely an example and the present inventive concept is not limited thereto.

During the operation of the semiconductor memory device, a voltage may be applied to the back gate electrode BG to adjust the threshold voltage of a vertical channel transistor. By adjusting the threshold voltage of the vertical channel transistor, leakage current may be controlled or reduced.

A back gate isolation pattern 111 may be disposed between the first active pattern AP1 and the second active pattern AP2 that are adjacent to each other in the second direction DR2. The back gate isolation pattern 111 may extend in the first direction DR1 to be disposed side by side with the back gate electrode BG.

The back gate isolation pattern 111 may be disposed on the back gate electrode BG. For example, the back gate isolation pattern 111 may be in contact with the back gate electrode BG. The back gate isolation pattern 111 may be disposed on the second surface BG_S2 of the back gate electrode BG. For example, the back gate isolation pattern 111 may be in contact with the second surface BG_S2 of the back gate electrode BG. The back gate isolation pattern 111 may be disposed between the back gate electrode BG and the data storage patterns DSP. The back gate isolation pattern 111 may include an upper surface 111_US facing the data storage patterns DSP.

The back gate isolation pattern 111 may be made of an insulating material. The back gate isolation pattern 111 may include, for example, silicon oxide, silicon oxynitride, or silicon nitride, but the present inventive concept is not limited thereto.

A back gate insulating pattern 113 may be disposed between the back gate electrode BG and the first active pattern AP1, and between the back gate electrode BG and the second active pattern AP2. The back gate insulating pattern 113 may be disposed between the back gate isolation pattern 111 and the first active pattern AP1, and between the back gate isolation pattern 111 and the second active pattern AP2.

The back gate insulating pattern 113 may extend along the second sidewall SS12 of the first active pattern AP1 and the second sidewall SS22 of the second active pattern AP2. The back gate insulating pattern 113 may extend along the first sidewall BG_SS1 of the back gate electrode BG and the second sidewall BG_SS2 of the back gate electrode BG.

The back gate insulating pattern 113 may be made of an insulating material. The back gate insulating pattern 113 may include, for example, silicon oxide, silicon oxynitride, a high-k insulating material having a higher dielectric constant than silicon oxide, or a combination thereof.

The back gate capping pattern 115 may be disposed between the bit line BL and the back gate electrode BG. The back gate capping pattern 115 may be disposed between the first active pattern AP1 and the second active pattern AP2, which are adjacent to the back gate capping pattern 115 in the second direction DR2. The back gate capping pattern 115 may extend in the first direction DR1 to be disposed with the back gate electrode BG. The back gate capping pattern 115 may be disposed on the first surface BG_S1 of the back gate electrode BG. The thickness of the back gate capping pattern 115 may vary. For example, the thickness of the portions of the back gate capping pattern 115 that are disposed between the bit lines BL may be different from the thickness of portions of the back gate capping pattern 115 that are disposed on the bit line BL, but the present inventive concept is not limited thereto.

The back gate capping pattern 115 may be made of an insulating material. The back gate capping pattern 115 may include, for example, at least one of silicon oxide, silicon oxynitride, or silicon nitride, but the present inventive concept is not limited thereto.

The first word line WL1 and the second word line WL2 may be disposed above the bit line BL and the shielding conductive pattern SL. Each of the first word line WL1 and the second word line WL2 may extend in the first direction DR1. The first word line WL1 and the second word line WL2 may be alternately arranged in the second direction DR2.

The first word line WL1 may be disposed on the first sidewall SS11 of the first active pattern AP1. The second word line WL2 may be disposed on the first sidewall SS21 of the second active pattern AP2. The first word line WL1 may be disposed on the first sidewall BG_SS1 of the back gate electrode BG. The second word line WL2 may be disposed on the second sidewall BG_SS2 of the back gate electrode BG. The first and second word lines WL1 and WL2 may be spaced apart from the back gate electrode BG in the second direction DR2.

In the semiconductor memory device according to embodiments of the present inventive concept, the first word line WL1 is not disposed on the second sidewall SS12 of the first active pattern AP1. The second word line WL2 is not be disposed on the second sidewall SS22 of the second active pattern AP2.

The first active patterns AP1 and the second active patterns AP2 may be disposed between the first word line WL1 and the second word line WL2 that are adjacent to each other in the second direction DR2. For example, the first word line WL1 and the second word line WL2 may be disposed between the first active patterns AP1 and the second active patterns AP2 that are adjacent to each other in the second direction DR2. For example, pairs of the first active pattern AP1 and the second active pattern AP2 may alternately arranged along the second direction DR2 with pairs of the first word line WL1 and the second word line WL2.

In the semiconductor memory device according to embodiments of the present inventive concept, the first word line WL1 and the second word line WL2 may be spaced apart from the bit lines BL and the data storage patterns DSP in the third direction DR3. The first word line WL1 and the second word line WL2 may be disposed between the bit line BL and the data storage patterns DSP.

Each of the first word line WL1 and the second word line WL2 may have a width in the second direction DR2. For example, the width of a first portion of the first word line WL1 and the width of a first portion of the second word line WL2, which are above the bit line BL, may be different from the width of a second portion of the first word line WL1 and the width of a second portion of the second word line WL2, which are above the shielding conductive pattern SL.

For example, each of the first word line WL1 and the second word line WL2 may include a first portion WLa and a second portion WLb. The width of the first portion WLa of the word line in the second direction DR2 may be smaller than the width of the second portion WLb of the word line in the second direction DR2. As an example, the first portion WLa of the word line may be disposed on the bit line BL. The second portion WLb of the word line may be disposed on the shielding conductive pattern SL. The second portion WLb of the word line may be disposed on the shielding conductive line pattern SLp.

Each of the first word line WL1 and the second word line WL2 may include the first portion WLa and the second portion WLb that are alternately disposed along the first direction DR1. In the first word line WL1, each of the first active patterns AP1 may be disposed between the second portions WLb of the first word line WL, which are adjacent to each other in the first direction DR1. In the second word line WL2, each of the second active patterns AP2 may be disposed between the second portions WLb of the second word line WL2, which are adjacent to each other in the first direction DR1.

In an embodiment of the present inventive concept, the width of the first portion WLa in the second direction DR2 may be the same as the width of the second portion WLb in the second direction DR2. In other words, the width of the first portions WLa of the first word line WL1 and the width of the first portions WLa of the second word line WL2 that are disposed above the bit line BL may be the same as the width of the second portions WLb of the first word line WL1 and the width of the second portions WLb of the second word line WL2 that are disposed above the shielding conductive pattern SL. For example, each of the first word line WL1 and the second word line WL2 may have a constant width above the bit line BL and the shielding conductive pattern SL. In this case, a gate insulating pattern GOX, which will be described later, may fill a space between neighboring first active patterns AP1of the first active patterns AP1 in the first direction DR1, and a space between neighboring second active patterns AP2 of the second active patterns AP2 in the first direction DR1.

Each of the first word line WL1 and the second word line WL2 may include a first surface WL_S1 and a second surface WL_S2 opposite to each other in the third direction DR3. The first surface WL_S1 of the first and second word lines WL1 and WL2 is closer to the bit line BL than the second surface WL_S2 of the first and second word lines WL1 and WL2. The first surface WL_S1 of the first and second word lines WL1 and WL2 faces the bit line BL. For example, the second surface WL_S2 of the first and second word lines WL1 and WL2 may be the upper surfaces of the first and second word lines WL1 and WL2. The first surface WL_S1 of the first and second word lines WL1 and WL2 may be the lower surfaces of the first and second word lines WL1 and WL2.

In a semiconductor memory device according to embodiments of the present inventive concept, a height H11 from the upper surface BL_US of the bit line BL to the second surface S22 of the second active pattern may be greater than a height H12 from the upper surface BL_US of the bit line BL to the second surface WL_S2 of the second word line WL2. With respect to the upper surface BL_US of the bit line BL, the second surface S12 of the first active pattern AP1 may be higher than the second surface WL_S2 of the first word line WL1.

The first word line WL1 will be described as an example. In one example, the height of the first word line WL1 in the third direction DR3 may be the same as the height of the back gate electrode BG in the third direction DR3. In another example, the height of the first word line WL1 in the third direction DR3 may be greater than the height of the back gate electrode BG in the third direction DR3. In another example, the height of the first word line WL1 in the third direction DR3 may be smaller than the height of the back gate electrode BG in the third direction DR3.

Further, in one example, with respect to the upper surface BL_US of the bit line BL, the height of the first surface WL_S1 of the first word line WL1 may be the same as the height of the first surface BG_S1 of the back gate electrode BG. In another example, the first surface WL_S1 of the first word line WL1 may be higher than the first surface BG_S1 of the back gate electrode BG. In another example, the first surface WL_S1 of the first word line WL1 may be lower than the first surface BG_S1 of the back gate electrode BG.

Furthermore, in one example, with respect to the upper surface BL_US of the bit line BL, the height of the second surface WL_S2 of the first word line WL1 may be the same as the height of the second surface BG_S2 of the back gate electrode BG. In another example, the second surface WL_S2 of the first word line WL1 may be higher than the second surface BG_S2 of the back gate electrode BG. In another example, the second surface WL_S2 of the first word line WL1 may be lower than the second surface BG_S2 of the back gate electrode BG.

The first surfaces WL_S1 of the first and second word lines WL1 and WL2 may be flat or substantially flat, but the present inventive concept is not limited thereto. The second surfaces WL_S2 of the first and second word lines WL1 and WL2 may be flat or substantially flat, but the present inventive concept is not limited thereto. Although it is illustrated that the first surface BG_S1 of the back gate electrode BG and the second surface BG_S2 of the back gate electrode BG are flat, the present inventive concept is not limited thereto.

Each of the first word line WL1 and the second word line WL2 may include a conductive material. Each of the first word line WL1 and the second word line WL2 may include, for example, at least one of a conductive semiconductor material, conductive metal nitride, conductive metal silicon nitride, metal carbonitride, conductive metal silicide, conductive metal oxynitride, a 2D material, or metal. Although the first word line WL1 and the second word line WL2 are each illustrated as a single film, this is merely an example and the present inventive concept is not limited thereto.

Gate insulating patterns GOX may be disposed between the first word line WL1 and the first active pattern AP1, and between the second word line WL2 and the second active pattern AP2. The first word line WL1 and the second word line WL2 may be disposed on the gate insulating patterns GOX. The gate insulating patterns GOX may extend in the first direction DR1 with the first word line WL1 and the second word line WL2.

The gate insulating pattern GOX may include, for example, silicon oxide, silicon oxynitride, a high-k insulating material having a higher dielectric constant than silicon oxide, or a combination thereof. The high-k insulating film may include, for example, at least one of metal oxide, metal oxynitride, metal silicon oxide, or metal silicon oxynitride, but the present inventive concept is not limited thereto.

The gate insulating pattern GOX may extend along the first sidewall SS11 of the first active pattern AP1, and may extend along the first sidewall SS21 of the second active pattern AP2. In a semiconductor memory device according to embodiments of the present inventive concept, the gate insulating pattern GOX is not be disposed between the first active pattern AP1 and a gate shielding pattern 145, and between the second active pattern AP2 and the gate shielding pattern 145.

A portion of the gate insulating pattern GOX may protrude toward the data storage pattern DSP and may extend closer to the data storage pattern DSP than the second surface S12 of the first active pattern AP1. A portion of the gate insulating pattern GOX may protrude toward the data storage pattern DSP and may extend closer to the data storage pattern DSP than the second surface S22 of the second active pattern AP2. In cross-sectional views such as FIGS. 2 and 4, with respect to the upper surface BL_US of the bit line, the uppermost portion of the gate insulating pattern GOX may be higher than each of the second surface S12 of the first active pattern AP1 and the second surface S22 of the second active pattern AP2.

The gate insulating pattern GOX may be disposed between the gate shielding pattern 145 and the first word line WL1 and between the gate shielding pattern 145 and the second word line WL2. The gate insulating pattern GOX may extend along the first surface WL_S1 of the first word line WL1 and the first surface WL_S1 of the second word line WL2.

In cross-sectional view, the gate insulating pattern GOX between the first active pattern AP1 and the first word line WL1 may be connected to the gate insulating pattern GOX between the second active pattern AP2 and the second word line WL2. For example, the gate insulating pattern GOX may be a single integrated structure that is between the first active pattern AP1 and the first word line WL1 and between the second active pattern AP2 and the second word line WL2. However, the present inventive concept is not limited thereto. In an embodiment of the present inventive concept, the gate insulating pattern GOX that is disposed between the first active pattern AP1 and the first word line WL1 may be separated from the gate insulating pattern GOX that is disposed between the second active pattern AP2 and the second word line WL2.

The gate shielding pattern 145 may be disposed between the first word line WL1 and the bit line BL, and between the second word line WL2 and the bit line BL. The gate shielding pattern 145 may be disposed on the first surfaces WL_S1 of the first and second word lines WL1 and WL2.

The gate shielding pattern 145 may include a upper surface and a lower surface which are opposite to each other in the third direction DR3. The lower surface of the gate shielding pattern 145 may face the bit line BL. The first word line WL1 and the second word line WL2 may be disposed on the upper surface of the gate shielding pattern 145. The gate insulating pattern GOX may extend along the upper surface of the gate shielding pattern 145.

The gate shielding pattern 145 may be formed of an insulating material. The gate shielding pattern 145 may include, for example, at least one of silicon oxide, silicon oxynitride, or silicon nitride, but the present inventive concept is not limited thereto.

A gate isolation pattern GSS may be disposed on the bit line BL. The gate isolation pattern GSS may be disposed on the gate shielding pattern 145. The gate isolation pattern GSS may be disposed between the bit line BL and the data storage patterns DSP.

The gate isolation pattern GSS may be disposed between the first word line WL1 and the second word line WL2, which are adjacent to each other in the second direction DR2. The first word line WL1 and the second word line WL2 may be separated from each other by the gate isolation pattern GSS. The gate isolation pattern GSS may extend in the first direction DR1 between the first word line WL1 and the second word line WL2. For example, the gate isolation pattern GSS may be in contact with the first word line WL1 and the second word line WL2.

The first word line WL1 may be disposed between the gate isolation pattern GSS and the first active pattern AP1. The second word line WL2 may be disposed between the gate isolation pattern GSS and the second active pattern AP2. The gate isolation pattern GSS may be disposed between the first sidewall SS11 of the first active pattern AP1 and the first sidewall SS21 of the second active pattern AP2. The gate isolation pattern GSS may cover the second surface WL_S2 of the first word line WL1 and the second surface WL_S2 of the second word line WL2. For example, the gate isolation pattern GSS may be in contact with the second surfaces WL_S2 of the first and second word lines WL1 and WL2.

The gate isolation pattern GSS may include a horizontal gate isolation pattern 143 and a vertical gate isolation pattern 144. The horizontal gate isolation pattern 143 may be disposed on the second surface WL_S2 of the first word line WL1 and the second surface WL_S2 of the second word line WL2. The horizontal gate isolation pattern 143 may be disposed between the first word line WL1 and the data storage pattern DSP, and between the second word line WL2 and the data storage pattern DSP. The vertical gate isolation pattern 144 may be disposed between a sidewall of the first word line WL1 and a sidewall of the second word line WL2. In an embodiment of the present inventive concept, the vertical gate isolation pattern 144 is not be disposed on the second surface WL_S2 of the first word line WL1 and the second surface WL_S2 of the second word line WL2.

The gate isolation pattern GSS may include an upper surface GSS_US facing the data storage patterns DSP. With respect to the upper surface BL_US of the bit line, the upper surface GSS_US of the gate isolation pattern is higher than the second surface S12 of the first active pattern AP1 and higher than the second surface S22 of the second active pattern AP1. For example, the height from the upper surface BL_US of the bit line BL to the upper surface GSS_US of the gate isolation pattern GSS is greater than the height H11, which is from the upper surface BL_US of the bit line BL to the second surface S22 of the second active pattern AP1.

The gate isolation pattern GSS may be made of an insulating material. The horizontal gate isolation pattern 143 and the vertical gate isolation pattern 144 may each include an insulating material. The horizontal gate isolation pattern 143 and the vertical gate isolation pattern 144 may each include one of, for example, silicon oxide, silicon oxynitride, or silicon nitride, but the present inventive concept is not limited thereto. Although the horizontal gate isolation pattern 143 and the vertical gate isolation pattern 144 are illustrated as a single film, this is an example, and the present inventive concept is not limited thereto.

The contact patterns BC may be disposed between the gate isolation pattern GSS and the back gate isolation pattern 111. Each of the contact patterns BC may be disposed on the first active pattern AP1 or the second active pattern AP2. Each of the contact patterns BC may be connected to the first active pattern AP1 or the second active pattern AP2. Each of the contact patterns BC may be connected to the second surface S12 of the first active pattern or the second surface S22 of the second active pattern.

The landing pads LP may be disposed on the corresponding contact patterns BC. The landing pads LP may be disposed above the first active pattern AP1 or the second active pattern AP2 corresponding thereto. Landing pads LP may be disposed between the first active patterns AP1 and the data storage patterns DSP, and between the second active patterns AP2 and the data storage patterns DSP. Each of the contact patterns BC may be disposed between the first active pattern AP1 and the landing pad LP or between the second active pattern AP2 and the landing pad LP.

Each of the landing pads LP may be connected to the second surface S12 of the first active pattern AP1 or the second surface S22 of the second active pattern AP2. For example, each of the landing pads LP may be electrically connected to the first active pattern AP1 or the second active pattern AP2.

The landing pads LP may be disposed between the gate isolation pattern GSS and the back gate isolation pattern 111. Each of the landing pads LP may include an upper surface LP_US facing the data storage patterns DSP and a lower surface facing the bit lines BL. Each of the landing pads LP may include a sidewall LP_SW connecting the upper surface LP_US of the landing pad LP and the lower surface of the landing pad LP to each other. The sidewall LP_SW of the landing pad LP may extend in the third direction DR3.

Each of the landing pads LP does not cover the upper surface 111_US of the back gate isolation pattern 111 and the upper surface GSS_US of the gate isolation pattern GSS. Each of the landing pads LP does not overlap the upper surface 111_US of the back gate isolation pattern 111 in the third direction DR3. Each of the landing pads LP does not overlap the upper surface GSS_US of the gate isolation pattern GSS in the third direction DR3.

For example, the upper surface LP_US of the landing pad LP may be disposed on the same plane as the upper surface 111_US of the back gate isolation pattern 111. The upper surface LP_US of the landing pad LP may be disposed on the same plane as the upper surface GSS_US of the gate isolation pattern GSS.

The gate insulating pattern GOX may extend along the sidewall LP_SW of the landing pad LP. The gate insulating pattern GOX, which protrudes beyond the second surface S12 of the first active pattern AP1 and the second surface S22 of the second active pattern AP1, may be disposed on the sidewall LP_SW of the landing pad LP. The gate insulating pattern GOX may extend to the upper surface LP_US of the landing pad LP.

The back gate insulating pattern 113 may extend along the sidewall LP_SW of the landing pad LP. The back gate insulating pattern 113 may extend to the upper surface LP_US of the landing pad LP.

A width W11 of the landing pad LP in the first direction DR1 may be equal or substantially equal to a width W12 of the second active pattern AP2 in the first direction DR1. For example, the width W11 of the landing pad LP, which is connected to the second active pattern AP2, in the first direction DR1 may be equal or substantially equal to the width W12 of the second active pattern AP2 in the first direction DR1. The width W11 of the landing pad LP in the first direction DR1 may be equal or substantially equal to the width of the first active pattern AP1 in the first direction DR1.

Each of the contact patterns BC may have a rectangular or square shape in a plan view. Each of the landing pads LP may have a rectangular or square shape in a plan view.

In FIGS. 4 and 5, the landing pad LP may include a pad internal interface LP_IF. The pad internal interface LP_IF may extend in the third direction DR3. In other words, the pad internal interface LP_IF may extend in the perpendicular direction. The pad internal interface LP_IF may extend to the upper surface LP_US of the landing pad LP. For example, the pad internal interface LP_IF may be formed during the process of depositing the landing pad LP.

In FIGS. 4 and 6, the landing pad LP may not include the pad internal interface LP_IF (see FIG. 5).

The contact patterns BC may include a conductive material. The contact pattern BC may include, for example, at least one of doped polysilicon, conductive metal nitride, conductive metal silicon nitride, metal carbonitride, conductive metal silicide, conductive metal oxide, conductive metal oxynitride, a 2D material, or metal. As an example, the contact pattern BC may include doped polysilicon.

The landing pad LP may include a conductive material. The landing pad LP may include, for example, at least one of doped polysilicon, conductive metal nitride, conductive metal silicon nitride, metal carbonitride, conductive metal silicide, conductive metal oxide, conductive metal oxynitride, a 2D material, or metal.

In the manufacturing process, the contact pattern BC and the landing pad LP are formed in a space in which the first and second active patterns AP1 and AP2 are at least partially removed, so that a separate patterning process for forming the contact pattern BC and the landing pad LP is not required.

In addition, since the contact pattern BC and the landing pad LP are formed in a space in which the first and second active patterns AP1 and AP2 are at least partially removed, the contact pattern BC and the landing pad LP may be formed in a self-alignment method. That is, a separate photo process is not required to form the contact pattern BC and landing pad LP.

Through this, the process for manufacturing a semiconductor memory device may be simplified. Additionally, the manufacturing cost for a manufacturing semiconductor memory device may be reduced.

In addition, in a plan view, the landing pad LP is connected to the channel patterns AP1 and AP2 as a whole, so that the contact area between the landing pad LP and the channel patterns AP1 and AP2 may be increased. As the contact area between the landing pad LP and the channel patterns AP1 and AP2 increases, the resistance between the landing pad LP and the channel patterns AP1 and AP2 may be reduced. As a result, performance and reliability of the semiconductor memory device may be increased.

An etch stop film 247 may be disposed on the landing pad LP, the back gate isolation pattern 111, and the gate isolation pattern GSS. The etch stop film 247 may extend along each of the upper surface LP_US of the landing pad, the upper surface 111_US of the back gate isolation pattern, and the upper surface GSS_US of the gate isolation pattern. For example, the etch stop film 247 may be in contact with the back gate isolation pattern 111 and the gate isolation pattern GSS. The etch stop film 247 may be made of an insulating material.

The data storage patterns DSP may be disposed above the first and second word lines WL1 and WL2 and the back gate electrodes BG. The data storage patterns DSP may be disposed above the second surfaces WL_S2 of the first and second word lines WL1 and WL2 and the second surface BG_S2 of the back gate electrode BG.

The data storage patterns DSP may be disposed above the first and second active patterns AP1 and AP2. For example, the data storage patterns DSP may be respectively disposed on the landing pads LP. The data storage patterns DSP may be connected to the landing pads LP. For example, each of the data storage patterns DSP may be in contact with the landing pad LP corresponding thereto.

The data storage patterns DSP may be respectively electrically connected to the first and second active patterns AP1 and AP2. As shown in FIG. 1, the data storage patterns DSP may be arranged in a matrix form along the first direction DR1 and the second direction DR2.

In one example, the data storage patterns DSP may be capacitors. The data storage patterns DSP may include a capacitor dielectric film 253 interposed between storage electrodes 251 and a plate electrode 255. The storage electrodes 251 may penetrate an etch stop film 247. For example, the storage electrode 251 may be in contact with the upper surface LP_US of the landing pad LP by penetrating the etch stop film 247. In a plan view, the storage electrode 251 may have various shapes, such as a circle, an ellipse, a rectangle, a square, a rhombus, a hexagon, and the like.

Each of the storage electrode 251 and the plate electrode 255 may include a conductive material, and may include, for example, at least one of a conductive semiconductor material, conductive metal nitride, conductive metal silicon nitride, metal carbonitride, conductive metal silicide, conductive metal oxide, conductive metal oxynitride, a 2D material, or metal. For example, the capacitor dielectric film 253 may include at least one of a ferroelectric material, an antiferroelectric material, or a paraelectric material. For example, the capacitor dielectric film 253 may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and a combination of a ferroelectric material, an antiferroelectric material, or a paraelectric material.

In addition, the data storage patterns DSP may be variable resistance patterns that can be switched into two resistance states by an electrical pulse that is applied to a memory element. For example, the data storage patterns DSP may include a phase-change material whose crystalline state changes depending on the amount of current, perovskite compounds, transition metal oxide, magnetic materials, ferromagnetic materials, or antiferromagnetic materials.

The upper insulating film 290 may be disposed on the data storage pattern DSP. The upper insulating film 290 includes an insulating material.

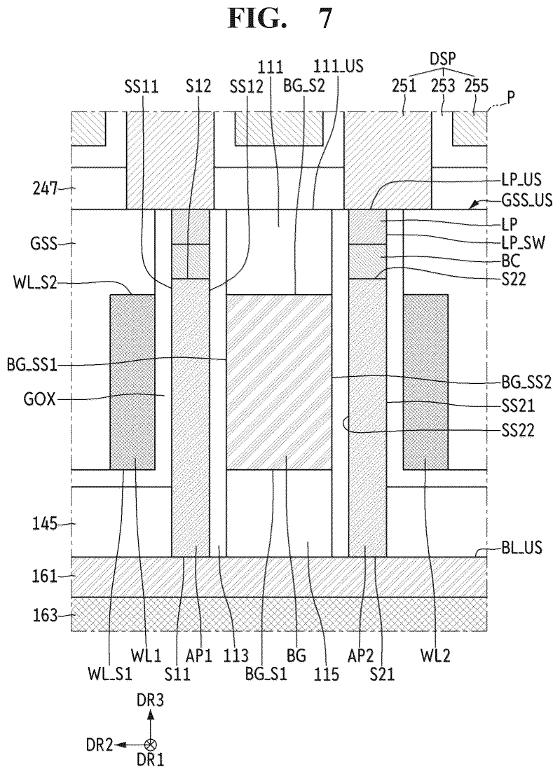

FIGS. 7 to 9 are diagrams each illustrating a semiconductor memory device according to embodiments of the present inventive concept. For simplicity of description, the following description will focus on differences from the description with reference to FIGS. 1 to 6, and redundant descriptions will be omitted or briefly discussed.

Referring to FIG. 7, in a semiconductor memory device according to embodiments of the present inventive concept, the gate isolation pattern GSS does not include the horizontal gate isolation pattern 143 (see FIG. 4) and the vertical gate isolation pattern 144 (see FIG. 4).

The gate isolation pattern GSS may be disposed between a sidewall of the first word line WL1 and a sidewall of the second word line WL2, and may be disposed on the second surface WL_S2 of the first word line WL1 and the second surface WL_S2 of the second word line WL2.

The gate isolation pattern GSS is illustrated as a single film, but the present inventive concept is not limited thereto. For example, the gate isolation pattern GSS may be a multilayer including an isolation liner and an isolation filling film.

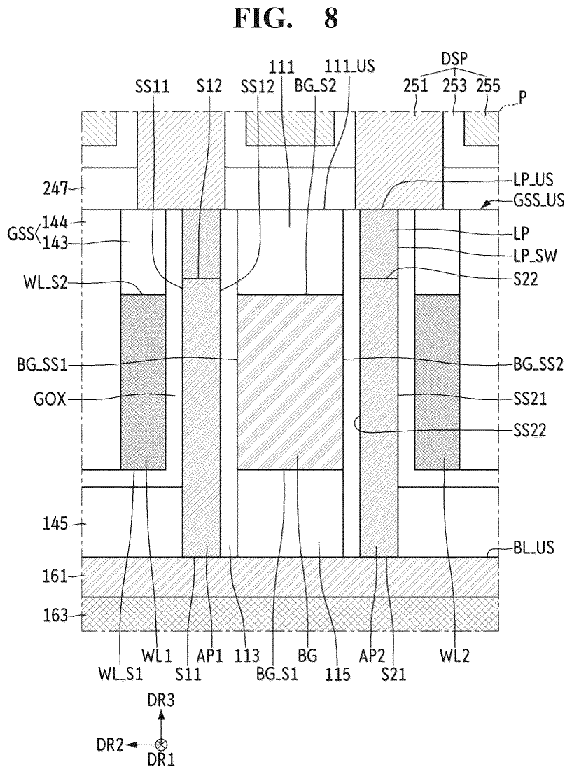

Referring to FIG. 8, a semiconductor memory device according to embodiments of the present inventive concept might not include the contact patterns BC.

The contact patterns BC might not be disposed between the first active pattern AP1 and the landing pad LP and between the second active pattern AP2 and the landing pad LP.

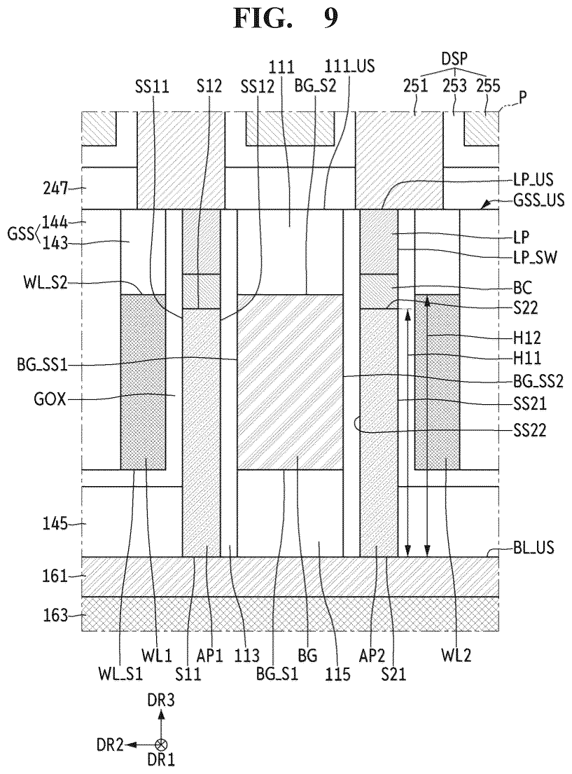

Referring to FIG. 9, in a semiconductor memory device according to embodiments of the present inventive concept, the height H11 from the upper surface BL_US of the bit line to the second surface S22 of the second active pattern AP2 may be less than the height H12 from the upper surface BL_US of the bit line to the second surface WL_S2 of the second word line WL2.

With respect to the upper surface BL_US of the bit line BL, the second surface S12 of the first active pattern AP1 may be lower than the second surface WL_S2 of the first word line WL1. With respect to the upper surface BL_US of the bit line BL, the second surface S22 of the second active pattern AP2 may be lower than the second surface WL_S2 of the second word line WL2.

In an embodiment of the present inventive concept, the height H11 from the upper surface BL_US of the bit line BL to the second surface S22 of the second active pattern AP2 may be equal to the height H12 from the upper surface BL_US of the bit line BL to the second surface WL_S2 of the second word line WL2.

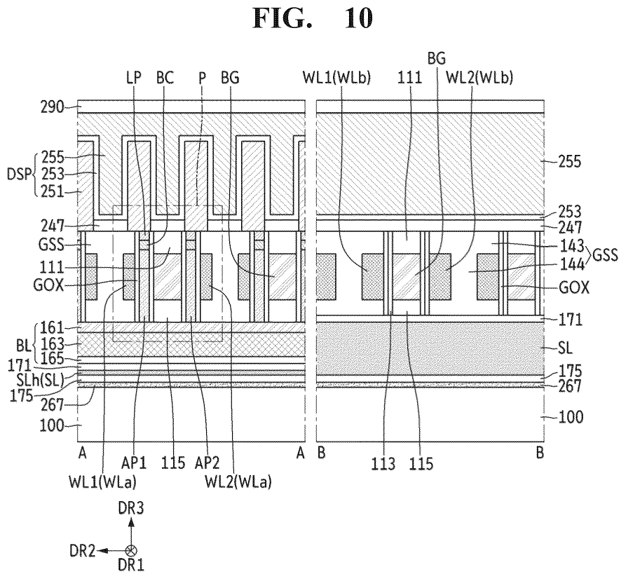

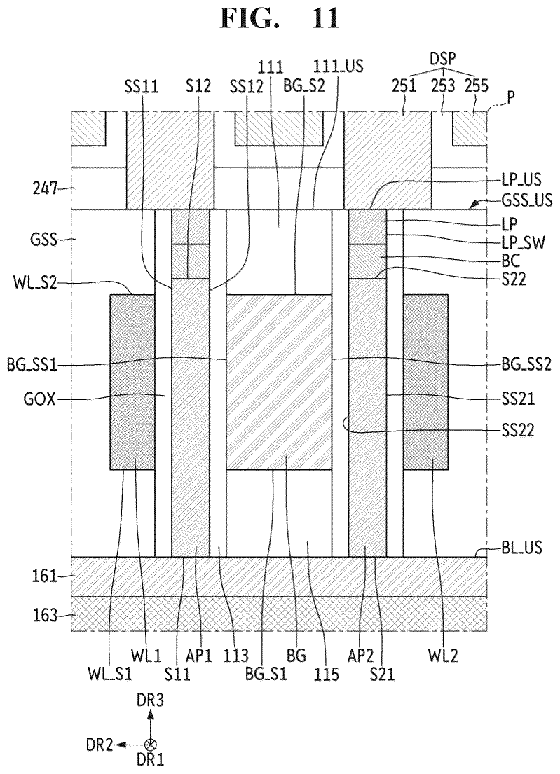

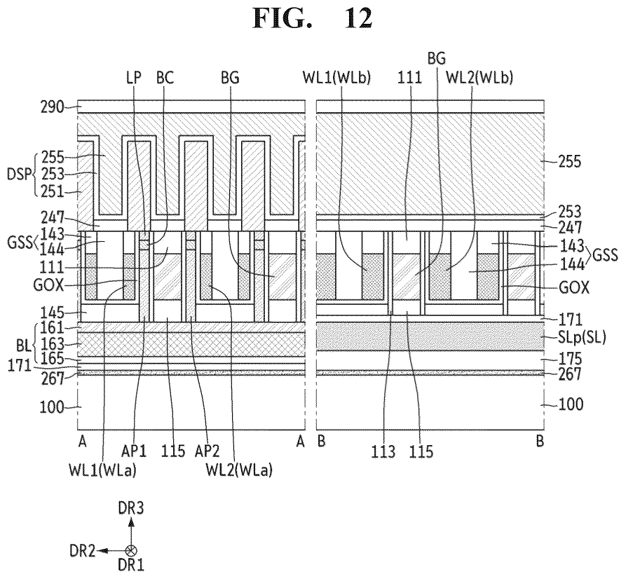

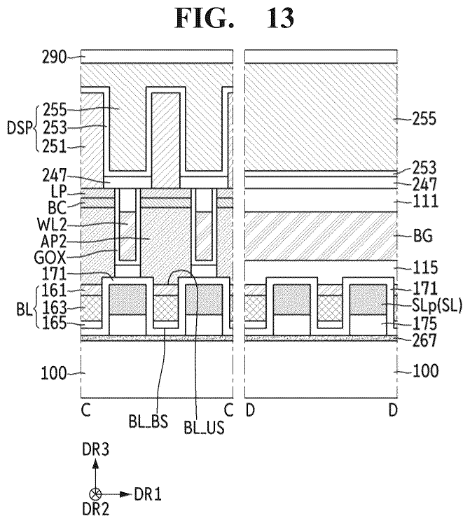

FIGS. 10 and 11 are diagrams illustrating a semiconductor memory device according to embodiments of the present inventive concept. FIGS. 12 and 13 are diagrams illustrating a semiconductor memory device according to embodiments of the present inventive concept. For simplicity of description, the following description will focus on differences from the description with reference to FIGS. 1 to 6, and redundant descriptions will be omitted or briefly discussed. For reference, FIG. 11 is an enlarged view of part P of FIG. 10.

Referring to FIGS. 10 and 11, a semiconductor memory device according to embodiments of the present inventive concept might not include the gate shielding pattern 145 (see FIG. 2).

The gate isolation pattern GSS may be disposed on the first surface WL_S1, a side surface, and the second surface WL_S2 of the first word line WL1 as a single body and the first surface WL_S1, a side surface, and the second surface WL_S2 of the second word line WL2 as a single body. The gate insulating pattern GOX does not extend along the first surface WL_S1 of the first word line WL1 and the first surface WL_S1 of the second word line WL2.

Referring to FIGS. 12 and 13, in a semiconductor memory device according to embodiments of the present inventive concept, the shielding conductive pattern SL may include the plurality of shielding conductive line patterns SLp without the shielding conductive plate SLh.

The shielding conductive pattern SL might not be disposed on the lower surface BL_BS of the bit line BL. For example, the shielding insulating capping film 175 may be in contact with the shielding conductive line pattern SLp.

The shielding insulating capping film 175 may have a line shape extending in the second direction DR2 along the shielding conductive line pattern SLp.

In an embodiment of the present inventive concept, the shielding insulating capping film 175 may have a shape of a flat plate. In other words, the shielding insulating capping film 175 may overlap the shielding conductive line pattern SLp in the third direction DR3.

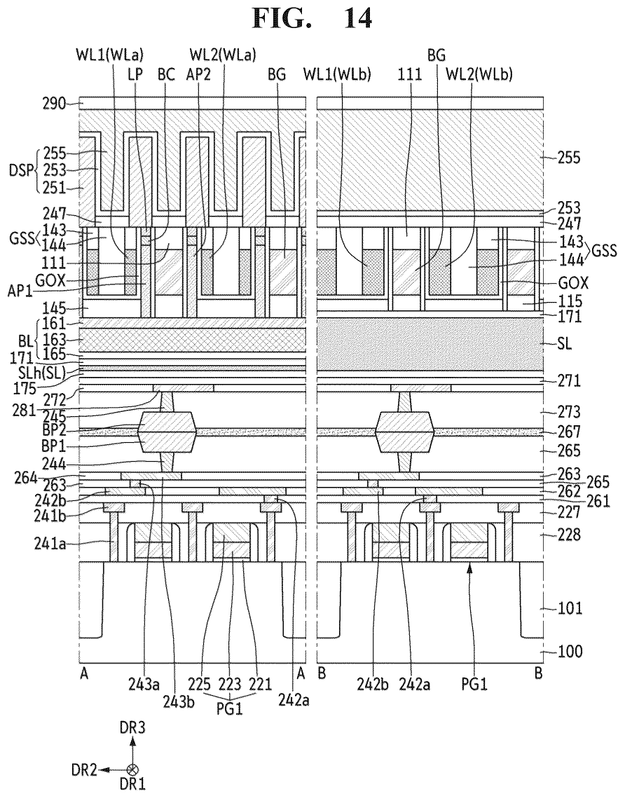

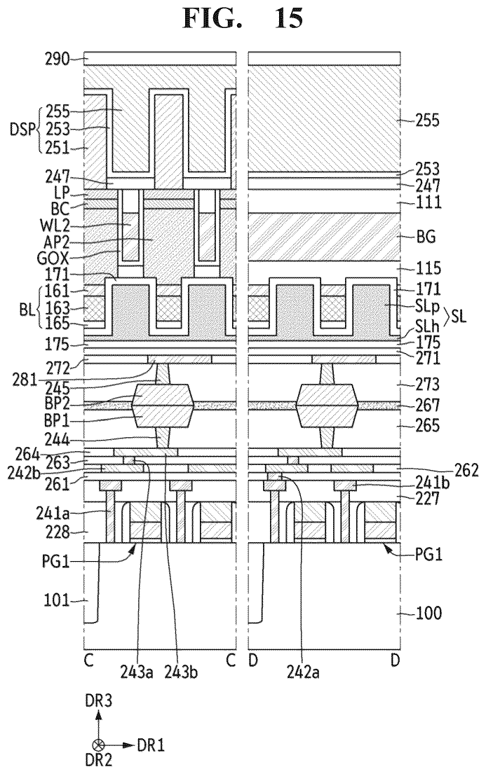

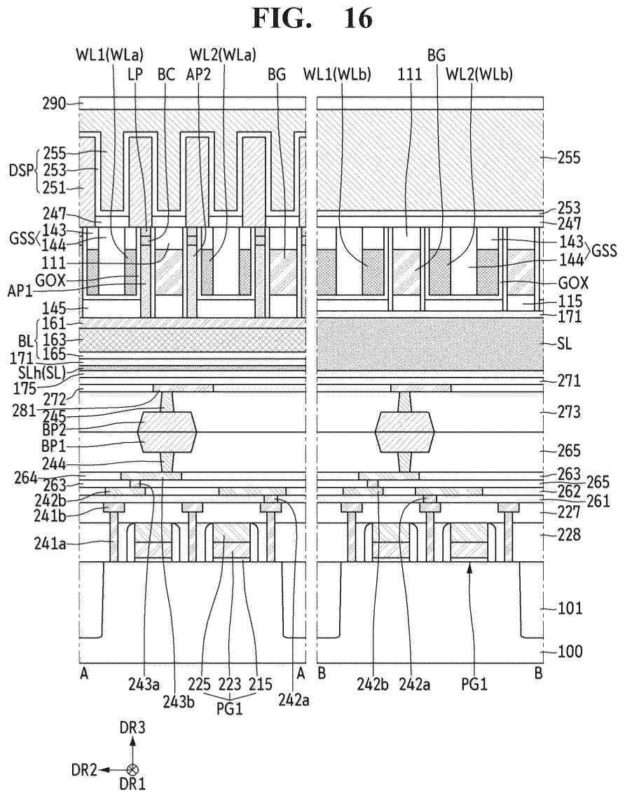

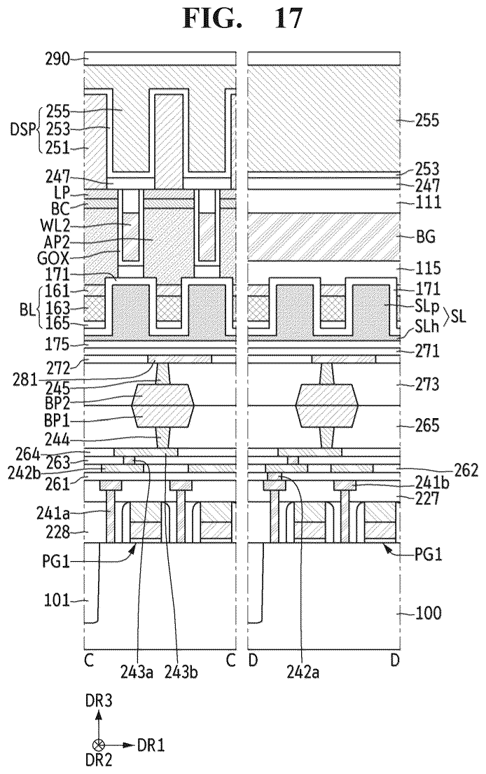

FIGS. 14 and 15 are diagrams illustrating a semiconductor memory device according to embodiments of the present inventive concept. FIGS. 16 and 17 are diagrams illustrating a semiconductor memory device according to embodiments of the present inventive concept. For simplicity of description, the following description will focus on differences from the description with reference to FIGS. 1 to 6, and redundant descriptions will be omitted or briefly discussed.

Referring to FIGS. 14 to 17, a semiconductor memory device according to embodiments of the present inventive concept may further include a first peri-gate structure PG1 disposed between the substrate 100 and the bit line BL.

A first element isolation film 101 may be disposed in the substrate 100. The first element isolation film 101 may define an active area in the substrate 100. The first element isolation film 101 includes an insulating material.

The first element isolation film 101 may be disposed in the substrate 100. The first element isolation film 101 may define an active area in the substrate 100.

The first peri-gate structure PG1 may be disposed on the substrate 100. For example, the first peri-gate structure PG1 may be disposed on the upper surface of the substrate 100. The first peri-gate structure PG1 may be disposed across the cell array region and the peripheral circuit region. For example, a part of the first peri-gate structure PG1 may be disposed in the cell array region of the substrate 100, and the remaining part of the first peri-gate structure PG1 may be disposed in the peripheral circuit region of the substrate 100.

The first peri-gate structure PG1 may be included in a sensing transistor, a transmission transistor, a driving transistor, and the like. For example, the first peri-gate structure PG1 included in the sensing transistor may be disposed on the cell array region of the substrate 100, but the present inventive concept is not limited thereto. The type of a transistor of a peripheral circuit disposed on the cell array region of the substrate 100 may vary depending on the design layout of the semiconductor memory device.

The first peri-gate structure PG1 may include a peri-gate insulating film 221, a first peri-lower conductive pattern 223, and a first peri-upper conductive pattern 225. The first peri-gate insulating film 221 may include, for example, silicon oxide, silicon oxynitride, a high-k insulating material having a dielectric constant higher than silicon oxide, or a combination thereof. The high-k insulating material may include, for example, at least one of metal oxide, metal oxynitride, metal silicon oxide, or metal silicon oxynitride, but is not limited thereto.

Each of the first peri-lower conductive pattern 223 and the first peri-upper conductive pattern 225 includes a conductive material. For example, the first peri-lower conductive pattern 223 and the first peri-upper conductive pattern 225 may each include at least one of a doped semiconductor material, conductive metal nitride, conductive metal silicon nitride, metal carbonitride, conductive metal silicide, conductive metal oxide, a 2D material, or metal. Although the first peri-gate structure PG1 is illustrated as including a plurality of conductive patterns, it is not limited thereto. In the semiconductor memory device according to embodiments of the present inventive concept, the 2D material may be a metallic material and/or a semiconductor material. The 2D material may include a 2D allotrope or a 2D compound. For example, the 2D material may include at least one of graphene, molybdenum disulfide (MoS₂), molybdenum diselenide (MoSe₂), tungsten diselenide (WSe₂), or tungsten disulfide (WS₂), but the present inventive concept is not limited thereto. That is, since the above-mentioned 2D materials are merely examples, the 2D materials that may be included in the semiconductor memory device of the present inventive concept is not limited thereto.

The first peri-gate structure PG1 may further include a first peri-gate mask pattern disposed on the first peri-upper conductive pattern 225. The first peri-gate mask pattern is made of an insulating material.

A first peri-lower insulating film 227 and a second peri-lower insulating film 228 are disposed on the upper surface of the substrate 100. The first peri-lower insulating film 227 and the second peri-lower insulating film 228 each include an insulating material.

A first peri-contact plug 241a and a first peri-wiring line 241b may be disposed in the first peri-lower insulating film 227 and the second peri-lower insulating film 228. The first peri-contact plug 241a and the first peri-wiring line 241b may be connected to a first source/drain region disposed on at least one side of the first peri-gate structure PG1. The first peri-contact plug 241a and the first peri-wiring line 241b may be connected to the conductive patterns 223 and 225 of the first peri-gate structure PG1. For example, the first peri-wiring line 241b may be the wiring line closest to the first peri-gate structure PG1 in the third direction DR3.

Although the first peri-contact plug 241a and the first peri-wiring line 241b are shown as different films, they are not limited thereto. For example, the first peri-contact plug 241a and the first peri-wiring line 241b may include the same material as each other and may be a single integrated structure. For example, an boundary or interface between the first peri-contact plug 241a and the first peri-wiring line 241b might not be distinguishable. Each of the first peri-contact plug 241a and the first peri-wiring line 241b includes a conductive material.

A first peri-upper insulating film 261, a second peri-upper insulating film 262, a third peri-upper insulating film 263, and a fourth peri-upper insulating film 264 may be disposed on the first peri-contact plug 241a and the first peri-wiring line 241b. Each of the first to fourth peri-upper insulating films 261, 262, 263, and 264 includes an insulating material. In an embodiment of the present inventive concept, an insulating film formed of a single film may be disposed on the first peri-contact plug 241a and the first peri-wiring line 241b.

A first peri-connection structure 242a and 242b may be connected to the first peri-wiring line 241b. The first peri-connection structure 242a and 242b may include a first peri-connection via 242a and a first peri-connection line 242b. Each of the first peri-connection via 242a and the first peri-connection line 242b includes a conductive material. Although the first peri-connection via 242a and the first peri-connection line 242b are shown as different films, they are not limited thereto. For example, the first peri-connection via 242a and the first peri-connection line 242b may include the same material as each other and may be a single integrated structure.

A second peri-connection structure 243a and 243b may be connected to the first peri-connection line 242b. The second peri-connection structure 243a and 243b may include a second peri-connection via 243a and a second peri-connection line 243b. Each of the second peri-connection via 243a and the second peri-connection line 243b includes a conductive material. Although the second peri-connection via 243a and the second peri-connection line 243b are shown as different films, they are not limited thereto. For example, the second peri-connection via 243a and the second peri-connection line 243b may include the same material as each other and may be a single integrated structure.

Although the first peri-connection structure 242a and 242b and the second peri-connection structure 243a and 243b are illustrated as being disposed on the first peri-gate structure PG1, they are not limited thereto. In an embodiment of the present inventive concept, only one peri-connection structure may be disposed on the first peri-gate structure PG1.

A fifth peri-upper insulating film 265 may be disposed on the second peri-connection structure 243a and 243b. The fifth peri-upper insulating film 265 includes an insulating material.

A lower bonding pad BP1 may be disposed on the first peri-gate structure PG1. The lower bonding pad BP1 may be connected to the second peri-connection structure 243a and 243b.

For example, at least one of the lower bonding pads BP1 may be connected to the first peri-gate structure PG1. At least one of the lower bonding pads BP1 may be connected to a first source/drain region disposed on at least one side of the first peri-gate structure PG1.

A lower pad plug 244 may connect the lower bonding pad BP1 to the second peri-connection line 243b. The lower bonding pad BP1 and the lower pad plug 244 may be disposed in the fifth peri-upper insulating film 265.

A first cell lower insulating film 271, a second cell lower insulating film 272, and a third cell lower insulating film 273 may be disposed on the fifth peri-upper insulating film 265. The first cell lower insulating film 271, the second cell lower insulating film 272, and the third cell lower insulating film 273 may be disposed on the lower bonding pad BP1.

The second cell lower insulating film 272 may be disposed between the first cell lower insulating film 271 and the third cell lower insulating film 273. The third cell lower insulating film 273 may be disposed between the second cell lower insulating film 272 and the fifth peri-upper insulating film 265. Each of the first cell lower insulating film 271, the second cell lower insulating film 272, and the third cell lower insulating film 273 includes an insulating material.

An upper bonding pad BP2 may be disposed on the lower bonding pad BP1. The upper bonding pad BP2 may be disposed on the fifth peri-upper insulating film 265.

The upper bonding pad BP2 may be connected to the lower bonding pad BP1. For example, the upper bonding pad BP2 may be in contact with the lower bonding pad BP1.

A first cell connection line 281 may be disposed on the upper bonding pad BP2. The first cell connection line 281 may be disposed between the upper bonding pad BP2 and the bit line BL. For example, the first cell connection line 281 may be connected to at least one of the bit line BL, the first word line WL1, the second word line WL2, or the shielding conductive pattern SL.

Although the first cell connection line 281 disposed at one metal level is illustrated as being disposed between the upper bonding pad BP2 and the bit line BL, this is merely an example and the present inventive concept is not limited thereto. A plurality of first cell connection lines 281 disposed at different metal levels may be disposed between the upper bonding pad BP2 and the bit line BL.

The upper pad plug 245 may connect the upper bonding pad BP2 to the first cell connection line 281. The upper bonding pad BP2 may be connected to the first cell connection line 281 through the upper pad plug 245.

The upper bonding pad BP2 and the upper pad plug 245 may be disposed in the third cell lower insulating film 273. The first cell connection line 281 may be disposed in the second cell lower insulating film 272.

The upper pad plug 245 and the lower pad plug 244 may include a conductive material including metal. Each of the lower bonding pad BP1 and the upper bonding pad BP2 may include a conductive material including metal. The first cell connection line 281 may include a conductive material including metal.

Although it is illustrated that each of the lower bonding pad BP1 and the upper bonding pad BP2 is a single film, this is merely an example, and the present inventive concept is not limited thereto. Each of the upper pad plug 245 and the lower pad plug 244 is illustrated as a single film, but the present inventive concept is not limited thereto. The first cell connection line 281 is shown as a single film, but the present inventive concept is not limited thereto.

At the interface between the lower bonding pad BP1 and the upper bonding pad BP2, the width of the lower bonding pad BP1 may be the same as the width of the upper bonding pad BP2. In an embodiment of the present inventive concept, at the interface between the lower bonding pad BP1 and the upper bonding pad BP2, the width of the lower bonding pad BP1 may be different from the width of the upper bonding pad BP2.

For example, at the interface between the lower bonding pad BP1 and the upper bonding pad BP2, the lower bonding pad BP1 may be aligned with the upper bonding pad BP2. In an embodiment of the present inventive concept, at the interface between the lower bonding pad BP1 and the upper bonding pad BP2, the lower bonding pad BP1 may be misaligned with the upper bonding pad BP2.

The shielding conductive pattern SL and the bit line BL may be disposed on the first peri-gate structure PG1. The shielding conductive pattern SL and the bit line BL may be disposed on the upper bonding pad BP2.

The first cell lower insulating film 271 may be disposed between the bit line BL and the first cell connection line 281, and between the shielding conductive pattern SL and the first cell connection line 281. The first cell lower insulating film 271 may be disposed between the shielding insulating liner 171 and the second cell lower insulating film 272, and between the shielding insulating capping film 175 and the second cell lower insulating film 272.

In FIG. 14 and FIG. 15, the bonding insulating film 267 may be disposed between the third cell lower insulating film 273 and the fifth peri-upper insulating film 265. The bonding insulating film 267 may be disposed between the first peri-gate structure PG1 and the shielding conductive pattern SL.

The bonding insulating film 267 may be disposed along an extension line of the interface that is positioned between the lower bonding pad BP1 and the upper bonding pad BP2. The interface between the lower bonding pad BP1 and the upper bonding pad BP2 may be a boundary between the lower bonding pad BP1 and the upper bonding pad BP2.

In FIGS. 16 and 17, the bonding insulating film 267 (see FIGS. 14 and 15) might not be disposed along the extension line of the interface between the lower bonding pad BP1 and the upper bonding pad BP2. The third cell lower insulating film 273 may be in contact with the fifth peri-upper insulating film 265.

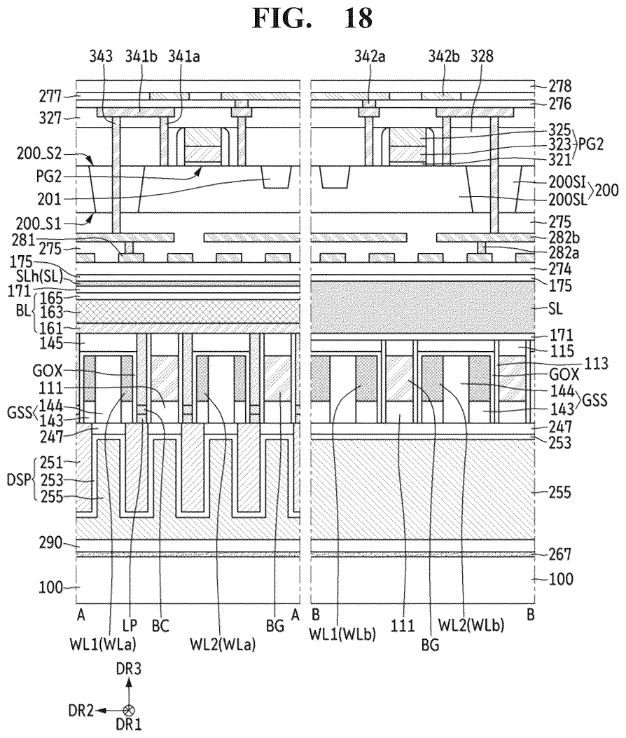

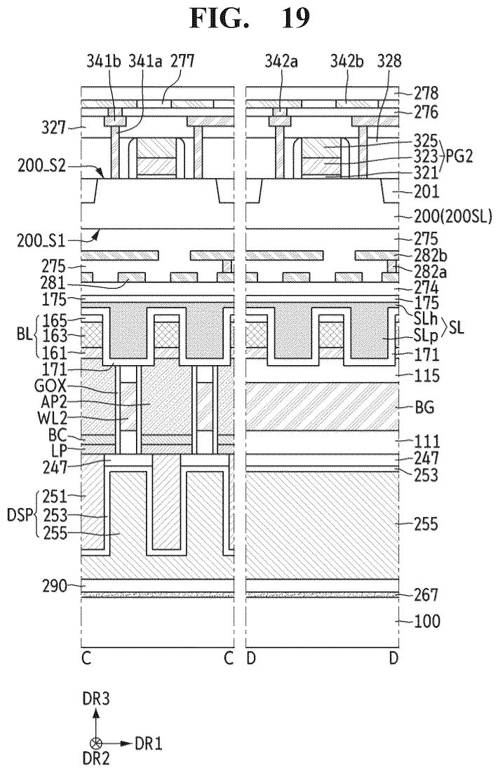

FIGS. 18 and 19 are diagrams illustrating a semiconductor memory device according to embodiments of the present inventive concept. For simplicity of description, the following description will focus on differences from the description with reference to FIGS. 1 to 6, and 14 to 17, and redundant descriptions will be omitted or briefly discussed.

Referring to FIGS. 18 and 19, the semiconductor memory device according to embodiments of the present inventive concept may include a peri-active substrate 200, a second peri-gate structure PG2, and a peri-connection through plug 343.

The data storage patterns DSP may be disposed between the substrate 100 and the bit lines BL.

A first cell upper insulating film 274 may be disposed on the bit line BL and the shielding conductive pattern SL. For example, the first cell upper insulating film 274 may be disposed on the shielding insulating capping film 175.

A second cell upper insulating film 275 may be disposed on the first cell upper insulating film 274. Each of the first cell upper insulating film 274 and the second cell upper insulating film 275 includes an insulating material.

The first cell connection line 281, a second cell connection via 282a, and a second cell connection line 282b may be disposed on the first cell upper insulating film 274. The first cell connection line 281, the second cell connection via 282a, and the second cell connection line 282b may be disposed in the second cell upper insulating film 275. Although it is illustrated that the first cell connection line 281 and the second cell connection line 282b are disposed at different metal levels from each other in the second cell upper insulating film 275, the present inventive concept is not limited thereto.

The second cell connection via 282a and the second cell connection line 282b may each include a conductive material. The second cell connection via 282a and the second cell connection line 282b are shown as different films, but the present inventive concept is not limited thereto. For example, the second cell connection via 282a and the second cell connection line 282b may include the same material as each other and may be a single integrated structure.

The peri-active substrate 200 may be disposed above the second cell connection line 282b. The peri-active substrate 200 may be spaced apart from the substrate 100 in the third direction DR3. The second cell connection via 282a and the second cell connection line 282b may be disposed between the substrate 100 and the peri-active substrate 200.

The peri-active substrate 200 includes a peri-semiconductor film 200SL and a peri-semiconductor isolation film 200SI. For example, the peri-active substrate 200 may include the plurality of peri-semiconductor isolation films 200SI.

The peri-semiconductor film 200SL includes a semiconductor material. The peri-semiconductor film 200SL may include, for example, silicon, silicon germanium, indium antimonide, lead tellurium compound, indium arsenide, indium phosphide, gallium arsenide, or gallium antimonide, but the present inventive concept is not limited thereto. In the following description, the peri-semiconductor film 200SL is described as a silicon film containing silicon.

The peri-semiconductor isolation film 200SI includes an insulating material. The peri-semiconductor isolation film 200SI is shown as a single film, but this is merely an example and the present inventive concept is not limited thereto.

The peri-active substrate 200 may include a first surface 200_S1 and a second surface 200_S2 which are opposite to each other in the third direction DR3. The first surface 200_S1 of the peri-active substrate may face the substrate 100 and the second cell connection line 282b.

The first surface 200_S1 of the peri-active substrate 200 and the second surface 200_S2 of the peri-active substrate 200 each include the peri-semiconductor film 200SL and the peri-semiconductor isolation film 200SI. In other words, the first surface 200_S1 of the peri-active substrate and the second surface 200_S2 of the peri-active substrate may each be defined by the peri-semiconductor film 200SL and the peri-semiconductor isolation film 200SI. For example, the peri-semiconductor isolation film 200SI may completely penetrate the per-semiconductor film 200L, and the upper and lower surfaces of the peri-semiconductor isolation film 200SI may be respectively coplanar with upper and lower surfaces of the per-semiconductor film 200L.

A second element isolation film 201 may be disposed in the peri-semiconductor film 200SL. The second element isolation film 201 may be formed on the second surface 200_S2 of the peri-active substrate. The second element isolation film 201 does not extend to the first surface 200_S1 of the peri-active substrate. The thickness of the second element isolation film 201 in the third direction DR3 is smaller than the thickness of the peri-semiconductor isolation film 200SI in the third direction DR3. The second element isolation film 201 includes an insulating material.

The second peri-gate structure PG2 may be disposed on the peri-semiconductor film 200SL. The second peri-gate structure PG2 may be disposed on the second surface 200_S2 of the peri-active substrate.

A second peri-gate structure PG2 may include a second peri-gate insulating film 321, a second peri-lower conductive pattern 323, and a second peri-upper conductive pattern 325. The second peri-gate insulating film 321 may include, for example, silicon oxide, silicon oxynitride, a high-k insulating material having a dielectric constant higher than that of silicon oxide, or a combination thereof. The second peri-lower conductive pattern 323 and the second peri-upper conductive pattern 325 may each include at least one of a doped semiconductor material, conductive metal nitride, conductive metal silicon nitride, metal carbonitride, conductive metal silicide, conductive metal oxide, a 2D material, or metal. Although the second peri-gate structure PG2 is illustrated as including a plurality of conductive patterns, the present inventive concept is not limited thereto.

In the semiconductor memory device according to embodiments of the present inventive concept, the bit lines BL and the data storage patterns DSP may be disposed between the substrate 100 and the second peri-gate structure PG2.

A third peri-lower insulating film 327 and a fourth peri-lower insulating film 328 are disposed on the second surface 200_S2 of the peri-active substrate 200. The third peri-lower insulating film 327 and the fourth peri-lower insulating film 328 each include an insulating material.

A second peri-contact plug 341a and a second peri-wiring line 341b may be disposed in the third peri-lower insulating film 327. In addition, the second peri-contact plug 341a may extend through the fourth peri-lower insulating film 328 to penetrate the third peri-lower insulating film 327. The second peri-contact plug 341a and the second peri-wiring line 341b may be disposed on the second surface 200_S2 of the peri-active substrate 200.

The second peri-contact plug 341a and the second peri-wiring line 341b may be connected to a second source/drain region disposed on at least one side of the second peri-gate structure PG2. For example, the second peri-contact plug 341a and the second peri-wiring line 341b may be connected to the conductive patterns 323 and 325 of the second peri-gate structure PG2. For example, the second peri-wiring line 341b may be a wiring line closest to the second peri-gate structure PG2 in the third direction DR3.

Although the second peri-contact plug 341a and the second peri-wiring line 341b are shown as different films, the present inventive concept is not limited thereto. Each of the second peri-contact plug 341a and the second peri-wiring line 341b includes a conductive material.

The peri-connection through plug 343 may be disposed between the second peri-wiring line 341b and the second cell connection line 282b. The peri-connection through plug 343 may connect the second peri-wiring line 341b to the second cell connection line 282b.

The peri-connection through plug 343 may penetrate the peri-active substrate 200. For example, the peri-connection through plug 343 may penetrate the peri-semiconductor isolation film 200SI. The peri-connection through plug 343 includes a conductive material.

A sixth peri-upper insulating film 276, a seventh peri-upper insulating film 277, and an eighth peri-upper insulating film 278 may be disposed on the second peri-contact plug 341a and the second peri-wiring line 341b. Each of the sixth to eighth peri-upper insulating films 276, 277, and 278 includes an insulating material. In an embodiment of the present inventive concept, an insulating film formed as a single film may be disposed on the second peri-contact plug 341a and the second peri-wiring line 341b.

A third peri-connection structure 342a and 342b may be connected to the second peri-wiring line 341b. The third peri-connection structure 342a and 342b may include a third peri-connection via 342a and a third peri-connection line 342b. Each of the third peri-connection via 342a and the third peri-connection line 342b includes a conductive material.

Although the third peri-connection via 342a and the third peri-connection line 342b are shown as different films, the present inventive concept is not limited thereto. For example, the third peri-connection via 342a and the third peri-connection line 342b may include the same material as each other and may be a single integrated structure. The third peri-connection structure 342a and 342b is shown as including the third peri-connection line 342b disposed at a single metal level, but this is merely an example and the present inventive concept is not limited thereto. Unlike the illustrated example, the third peri-connection structure 342a and 342b may include the plurality of third peri-connection lines 342b disposed at two different metal levels.

Unlike the illustrated example, the bit lines BL may be disposed between the data storage patterns DSP and the substrate 100. In this case, the first cell upper insulating film 274 may be disposed on the data storage patterns DSP.

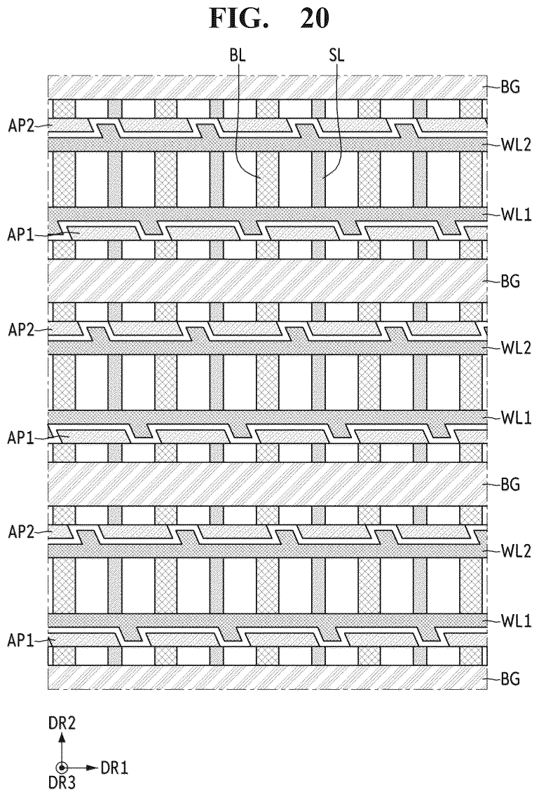

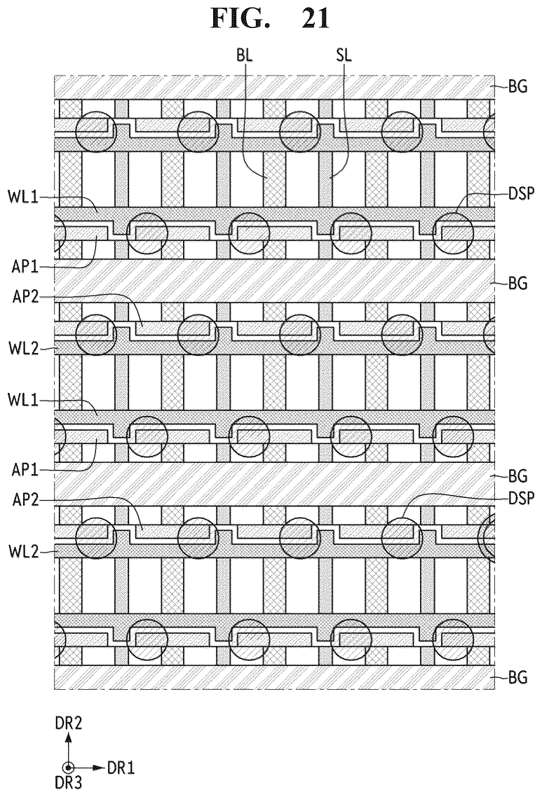

FIGS. 20 and 21 are diagrams each illustrating a semiconductor memory device according to embodiments of the present inventive concept. For simplicity of description, the following description will focus on differences from the description with reference to FIGS. 1 to 19, and redundant descriptions will be omitted or briefly discussed.

Referring to FIG. 20, in the semiconductor memory device according to embodiments of the present inventive concept, the first and second active patterns AP1 and AP2 may be alternately arranged in an oblique direction with respect to the first direction DR1 and the second direction DR2. In this case, the oblique direction may be parallel to the upper surface of the substrate 100. For example, the first active patterns AP1 may be misaligned with the second active patterns AP2, from a plan view.

In a plan view, each of the first and second active patterns AP1 and AP2 may have a parallelogram shape or a rhombus shape. Since the first and second active patterns AP1 and AP2 are disposed in the oblique direction, it is possible to reduce coupling between the first and second active patterns AP1 and AP2 facing each other in the second direction DR2.

Referring to FIG. 21, in a semiconductor memory device according to embodiments of the present inventive concept, the data storage patterns DSP may be arranged in a zigzag arrangement or honeycomb shape in a plan view.

Through this, the semiconductor memory device described with reference to FIGS. 14 and 15 may be fabricated.

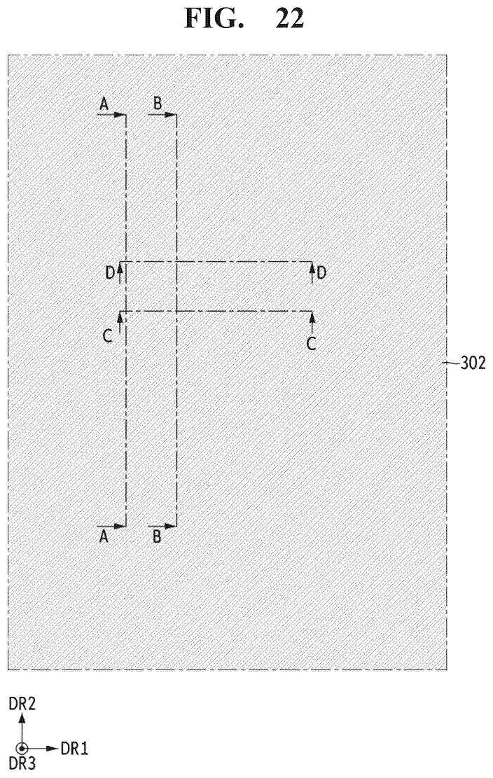

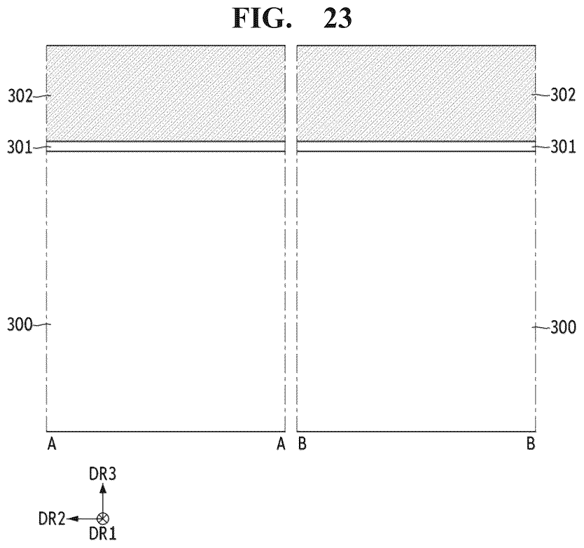

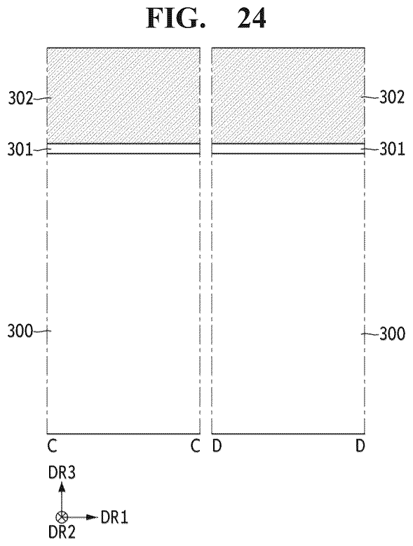

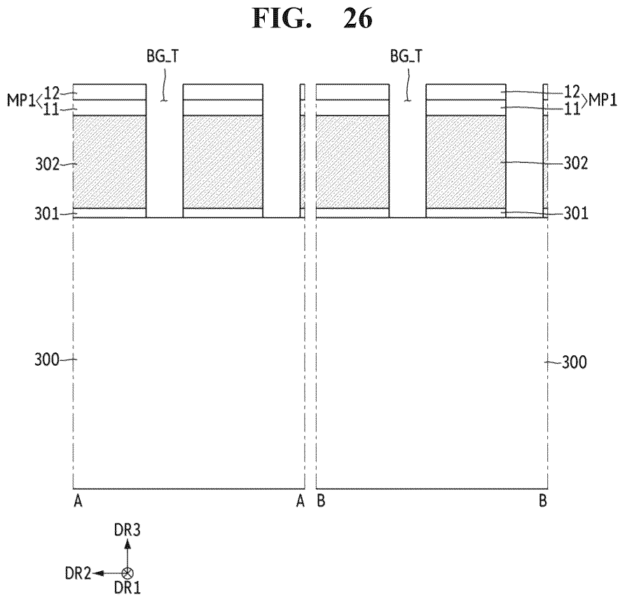

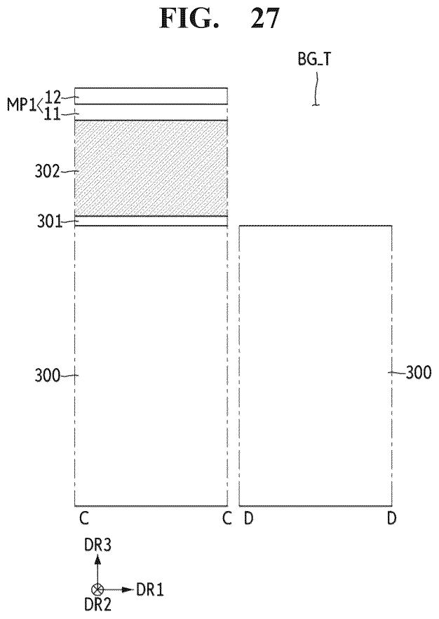

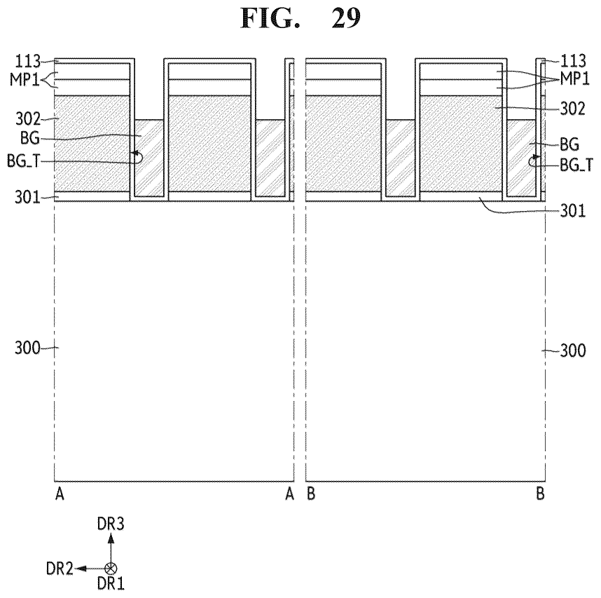

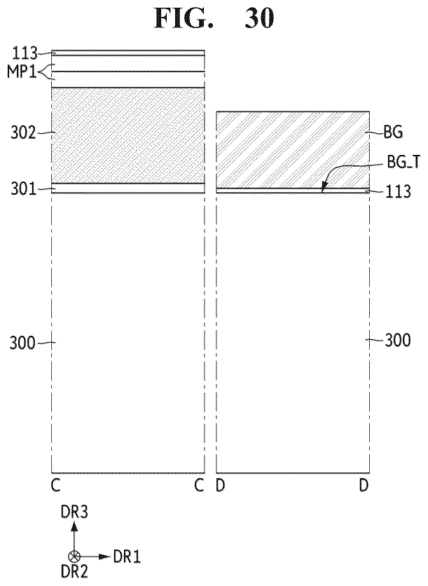

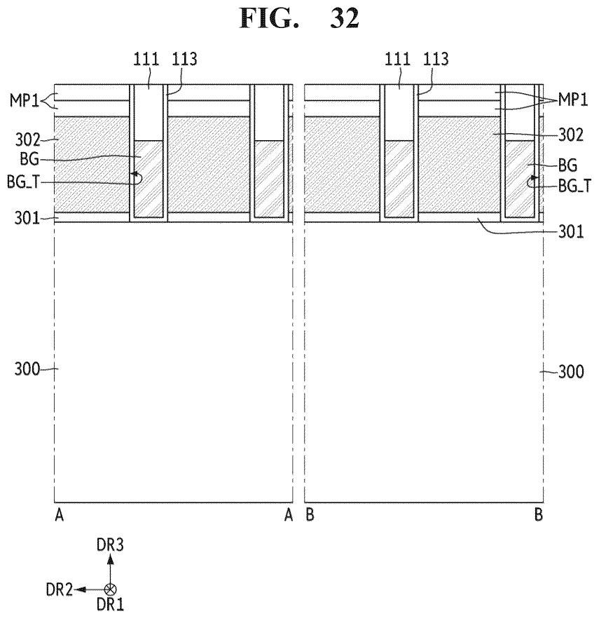

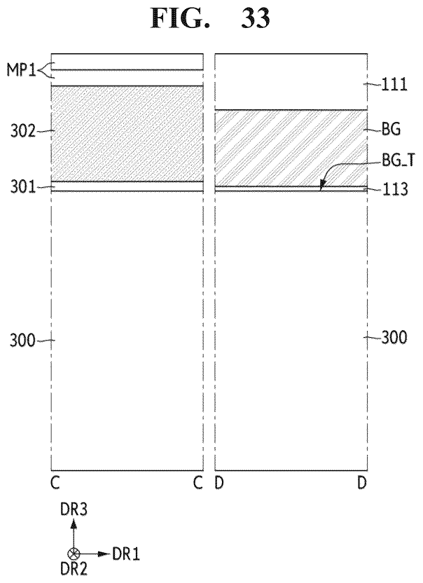

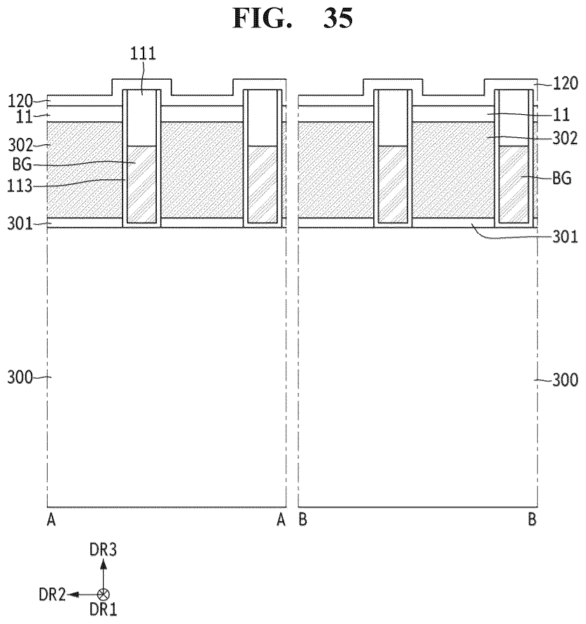

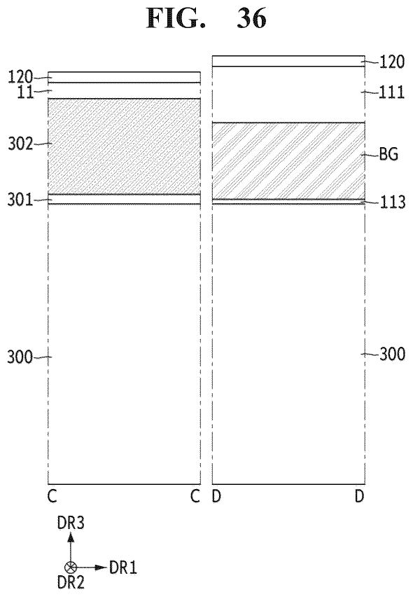

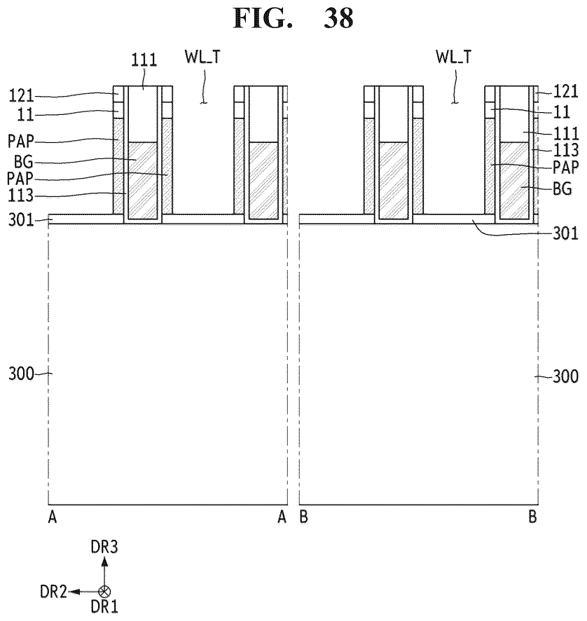

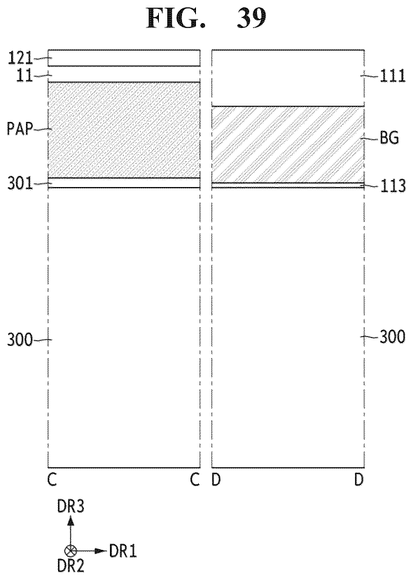

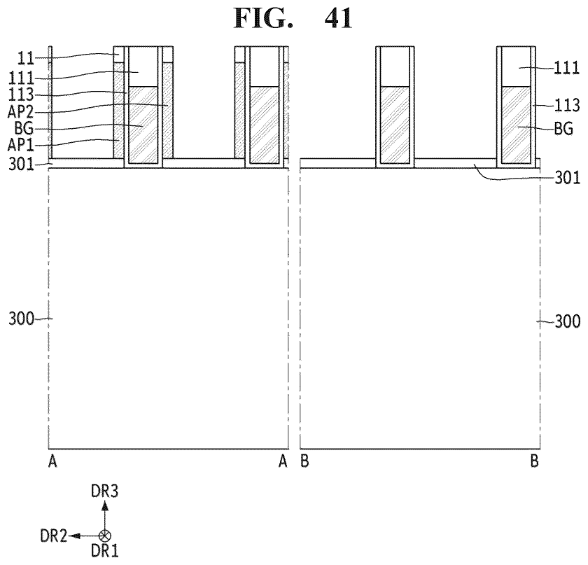

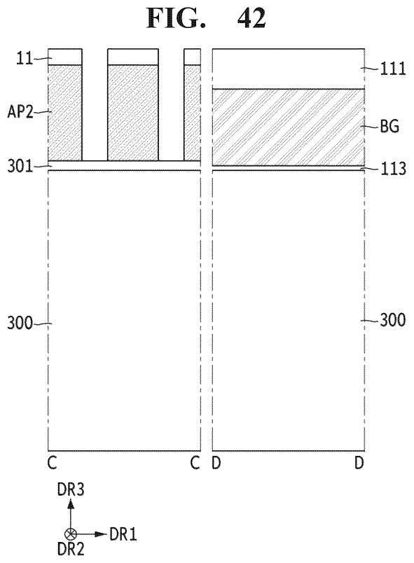

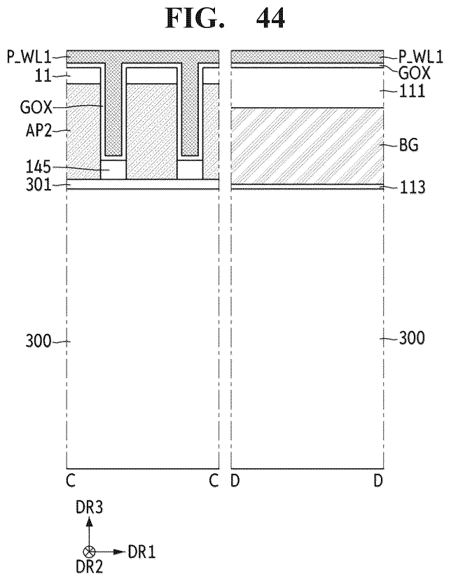

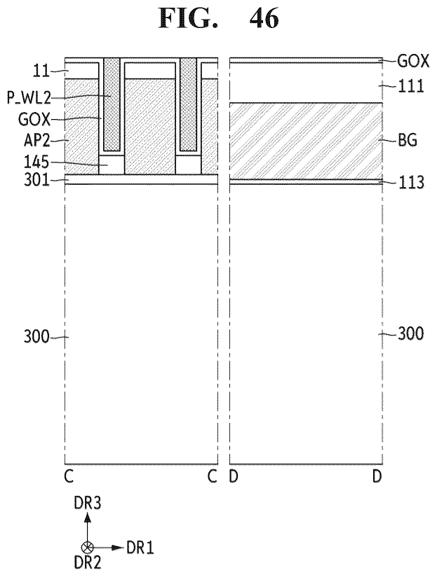

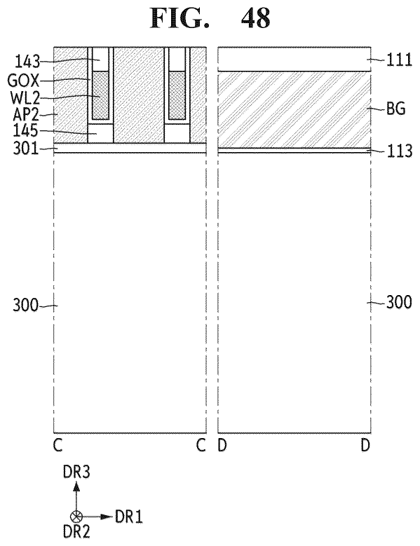

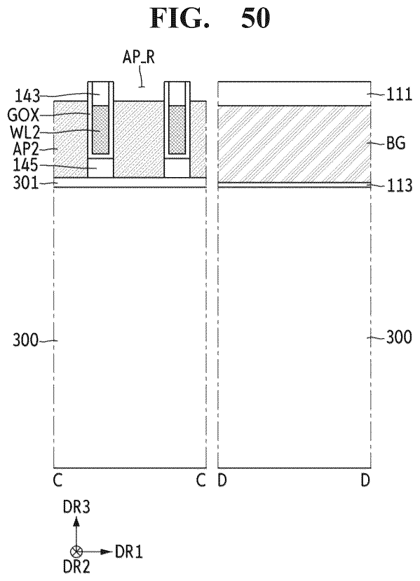

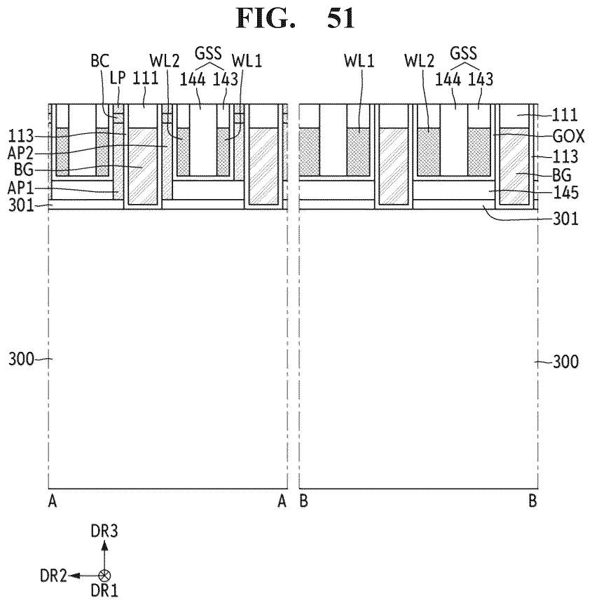

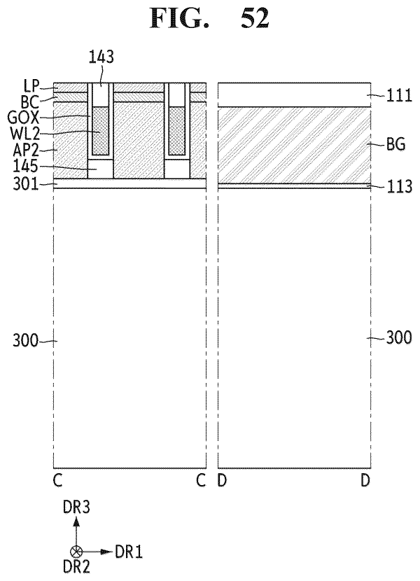

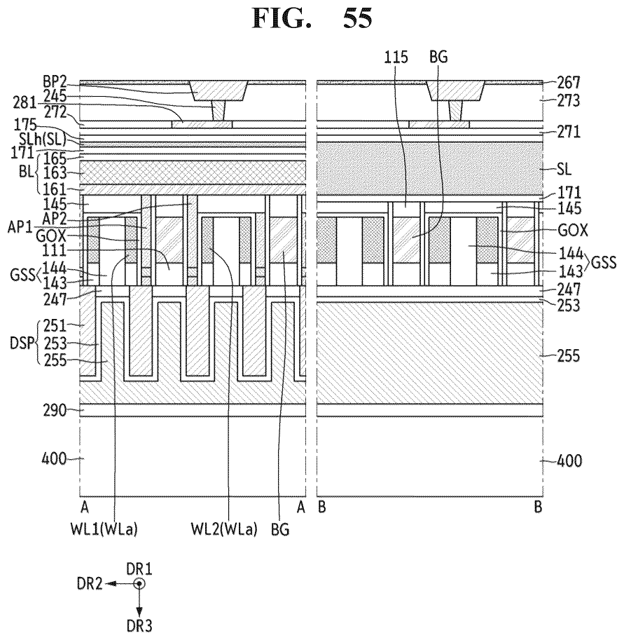

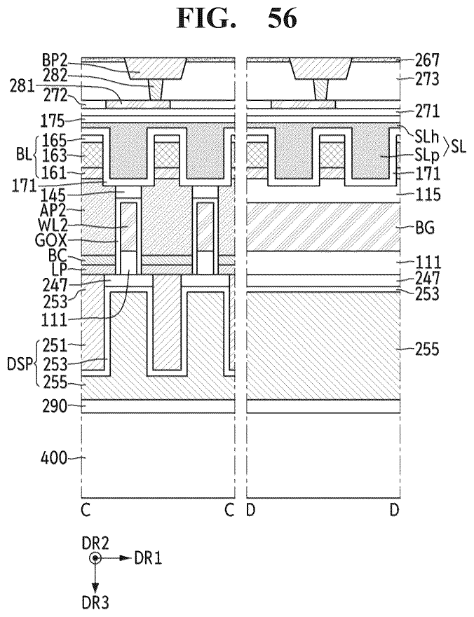

FIGS. 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, and 56 are views illustrating intermediate steps of a method for fabricating a semiconductor memory device according to embodiments of the present inventive concept.

Referring to FIGS. 22 to 25, a sub-substrate structure including a first sub-substrate 300, a buried insulating layer 301 and an active layer 302 may be provided.

The buried insulating layer 301 and the active layer 302 may be provided on the first sub-substrate 300. The first sub-substrate 300, the buried insulating layer 301, and the active layer 302 may be a silicon-on-insulator substrate (i.e., an SOI substrate). The first sub-substrate 300 may be a semiconductor substrate. The first sub-substrate 300 may be, for example, a silicon substrate, a germanium substrate, and/or a silicon-germanium substrate. In the following description, it is assumed that the first sub-substrate 300 is a silicon substrate.

The buried insulating layer 301 may be a buried oxide (BOX) formed by a separation by implanted oxygen (SIMOX) method or a bonding and layer transfer method. In addition, the buried insulating layer 301 may be an insulating film formed by a chemical vapor deposition (CVD) method. The buried insulating layer 301 may include, for example, silicon oxide, silicon nitride, silicon oxynitride, and/or a low dielectric constant insulating material.

The active layer 302 may be a single crystal semiconductor film. The active layer 302 may be, for example, a single crystal silicon substrate, a germanium substrate, and/or a silicon-germanium substrate. The active layer 302 may have first and second surfaces which are opposite to each other in the third direction DR3. For example, the second surface of the active layer 302 may be in contact with the buried insulating layer 301.

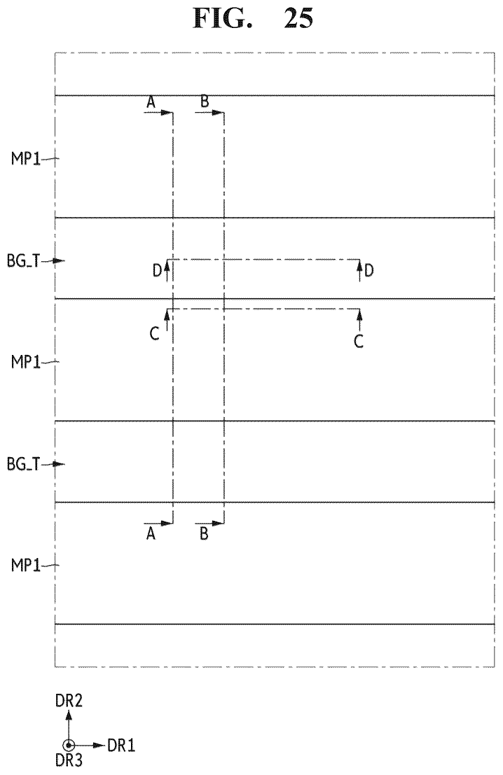

Referring to FIGS. 25 to 27, a mask pattern MP1 may be formed on the active layer 302.

The mask pattern MP1 may have line-shaped openings extending along the first direction DR1. The mask pattern MP1 may include a lower mask film 11 and an upper mask film 12 that are sequentially stacked on the active layer 302. The upper mask film 12 may be formed of a material having etching selectivity with respect to the lower mask film 11. For example, the lower mask film 11 may include silicon oxide, and the upper mask film 12 may include silicon nitride, but the present inventive concept is not limited thereto.

Subsequently, the active layer 302 may be anisotropically etched by using the mask pattern MP1 as an etching mask. Accordingly, back gate trenches BG_T may be formed in the active layer 302 to extend in the first direction DR1. The back gate trenches BG_T may expose the first sub-substrate 300 and may be spaced apart from each other by a predetermined interval in the second direction DR2.

In an embodiment of the present inventive concept, the buried insulating layer 301 may not be removed while the back gate trenches BG_T are formed, so that the first sub-substrate 300 may not be exposed. Instead, the buried insulating layer 301 may be exposed by the back gate trenches BG_T.

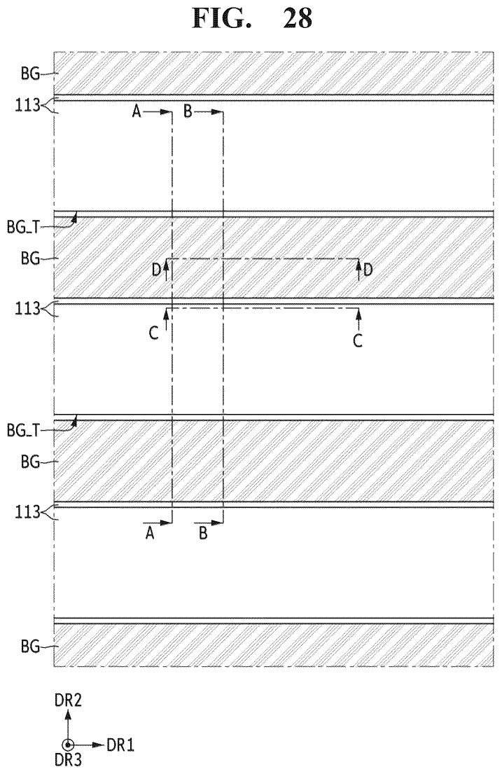

Referring to FIGS. 28 to 30, the back gate insulating pattern 113 and the back gate electrodes BG may be formed in the back gate trench BG_T.

For example, the back gate insulating pattern 113 may be formed along the sidewall and the lower surface of the back gate trench BG_T and the upper surface of the mask pattern MP1. A back gate conductive film may be formed on the back gate insulating pattern 113. The back gate conductive film may fill the back gate trench BG_T. Next, the back gate electrodes BG may be formed to extend in the first direction DR1 by isotropically etching the back gate conductive film. The back gate electrodes BG may fill a part of the back gate trench BG_T.

Meanwhile, according to embodiments of the present inventive concept, a gas phase doping (GPD) process or a plasma doping (PLAD) process may be performed before forming the back gate insulating pattern 113. Through the above process, the active layer 302 exposed by the back gate trench BG_T may be doped with impurities.

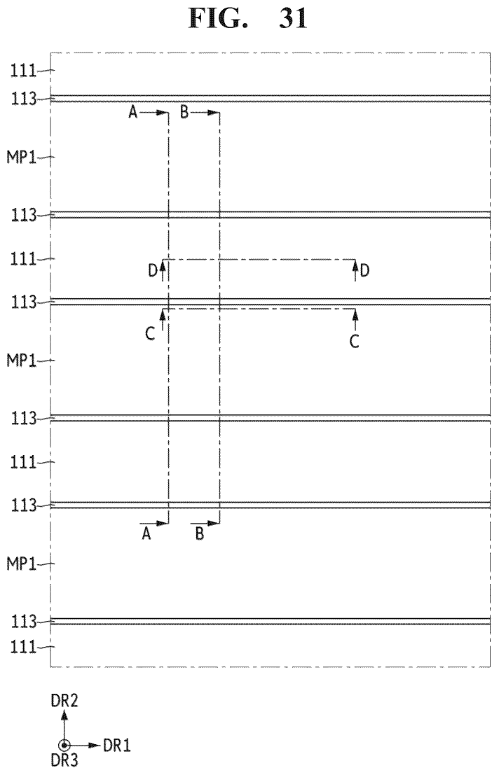

Referring to FIGS. 31 to 33, the back gate isolation patterns 111 may be formed on the back gate electrode BG.

The back gate isolation pattern 111 may fill the remaining part of the back gate trench BG_T. When the back gate isolation pattern 111 and the back gate insulating pattern 113 are made of the same material (e.g., silicon oxide), the back gate insulating pattern 113 that is disposed on the upper surface of the mask pattern MP1 may be removed while the back gate isolation pattern 111 is formed.

Meanwhile, before forming the back gate isolation pattern 111, a gas phase doping (GPD) process or a plasma doping (PLAD) process may be performed. Through this, impurities may be doped into the active layer 302 through the back gate trench BG_T in which the back gate electrode BG has been formed.

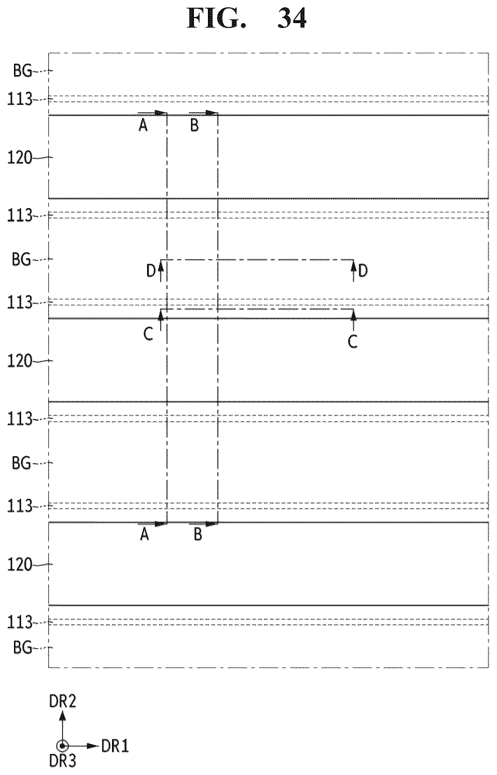

Referring to FIGS. 34 to 36, after forming the back gate isolation patterns 111, the upper mask film 12 may be removed.

The back gate isolation patterns 111 may have a shape that protrudes upward beyond the upper surface of the lower mask film 11.

Subsequently, a spacer film 120 may be formed along the upper surface of the lower mask film 11, the sidewalls of the back gate insulating patterns 113, and the upper surfaces of the back gate isolation patterns 111. The spacer film 120 may be formed to have a substantially uniform thickness. Widths of active patterns of vertical channel transistors may be determined according to the deposition thickness of the spacer film 120.

The spacer film 120 may be made of an insulating material. The spacer film 120 may include, for example, silicon oxide, silicon oxynitride, silicon nitride, silicon carbide (SiC), silicon carbon nitride (SiCN), and a combination thereof.

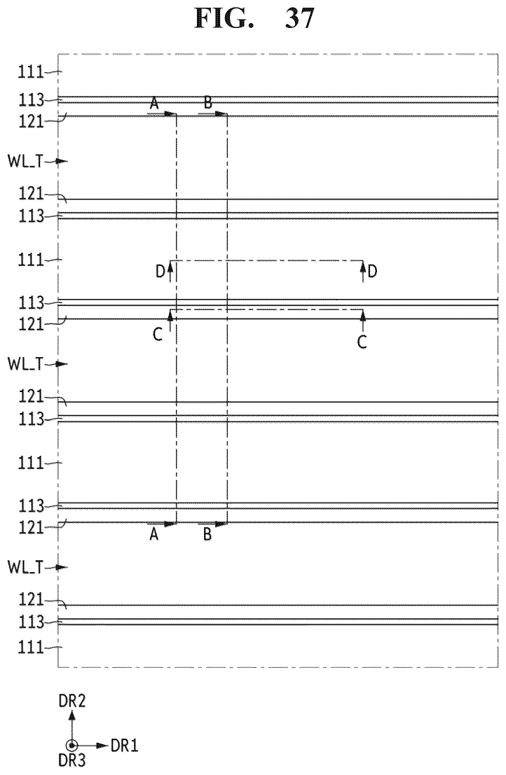

Referring to FIGS. 37 to 39, a pair of spacer patterns 121 may be formed on the sidewall of the back gate insulating pattern 113 by performing an anisotropic etching process on the spacer film 120.

An anisotropic etching process may be performed on the active layer 302 using the spacer pattern 121 as an etching mask. Through this, pre-active patterns PAP may be formed on both sides of each of the back gate insulating patterns 113. As the pre-active patterns PAP are formed, the buried insulating layer 301 may be exposed.

The pre-active patterns PAP may extend in the first direction DR1 parallel to the back gate electrode BG. While the pre-active pattern PAP is formed, word line trenches WL_T may be formed between neighboring pre-active patterns PAP of the pre-active patterns PAP in the second direction DR2.

Referring to FIGS. 37 to 42, a sacrificial film may be formed to fill the word line trench WL_T. A pattern mask may be formed on the sacrificial film. The pattern mask may have a line shape extending in the second direction DR2. As another example, the pattern mask may have a line shape extending in an oblique direction with respect to the first direction DR1 and the second direction DR2. Sacrificial openings may be formed in the sacrificial film by etching the sacrificial film using the pattern mask as an etching mask.

The first active patterns AP1 and the second active patterns AP2 may be formed on both sides of the back gate electrode BG by etching the pre-active patterns PAP that is exposed through the sacrificial openings. The first active patterns AP1 may be formed on a first sidewall of the back gate electrode BG and may be spaced apart from the first sidewall of the back gate electrode BG in the first direction DR1. The second active patterns AP2 may be formed on a second sidewall of the back gate electrode BG and may be spaced apart from the second sidewall of the back gate electrode BG in the first direction DR1. As the first active pattern AP1 and the second active pattern AP2 are formed, the sacrificial openings may expose a part of the back gate insulating pattern 113.

Subsequently, the sacrificial film, the pattern mask and the spacer pattern 121 may be removed. The first lower mask film 11 may remain on the first active pattern AP1 and the second active pattern AP2. The buried insulating layer 301 may be exposed.

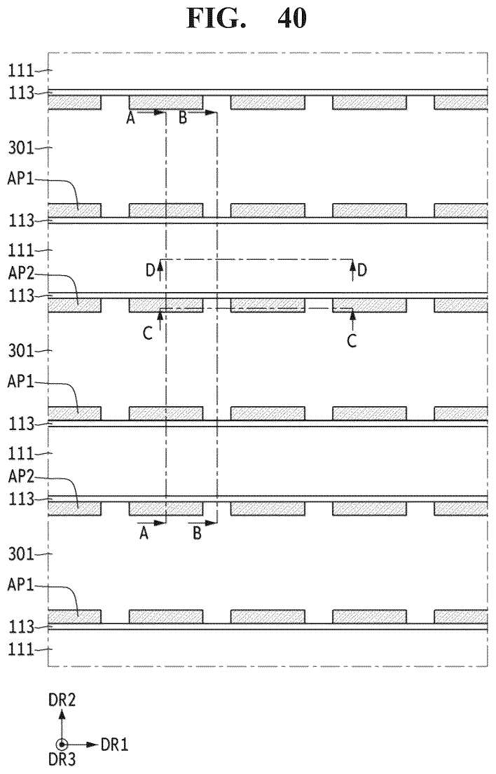

Referring to FIGS. 40 to 45, the gate shielding pattern 145 may be formed in the word line trench WL_T.

The gate shielding pattern 145 may fill a part of the word line trench WL_T. The gate shielding pattern 145 may be formed on the buried insulating layer 301.

Subsequently, the gate insulating pattern GOX may be formed along the sidewall of the first active pattern AP1, the sidewall of the second active pattern AP2, and the upper surface of the back gate isolation pattern 111. The gate insulating pattern GOX may be formed along an exposed surface of the gate shielding pattern 145. The exposed surface of the gate shielding pattern 145 may be the upper surface of the gate shielding pattern 145.

For example, the gate insulating pattern GOX may be formed using at least one of a physical vapor deposition (PVD) method, a thermal chemical vapor deposition (thermal CVD) method, a low pressure chemical vapor deposition (LPCVD) method, a plasma enhanced chemical vapor deposition (PECVD) method, or an atomic layer deposition (ALD) method. However, the present inventive concept is not limited thereto.

In an embodiment of the present inventive concept, the gate shielding pattern 145 might not be formed before the gate insulating pattern GOX is formed.

Subsequently, a first pre-word line pattern P_WL1 may be formed on the gate insulating pattern GOX. The first pre-word line pattern P_WL1 may be formed along the profile of the gate insulating pattern GOX. The first pre-word line pattern P_WL1 may be formed along the sidewall of the first active pattern AP1, the sidewall of the second active pattern AP2, and the upper surface of the back gate isolation pattern 111. The first pre-word line pattern P_WL1 may be formed along the upper surface of the gate shielding pattern 145.

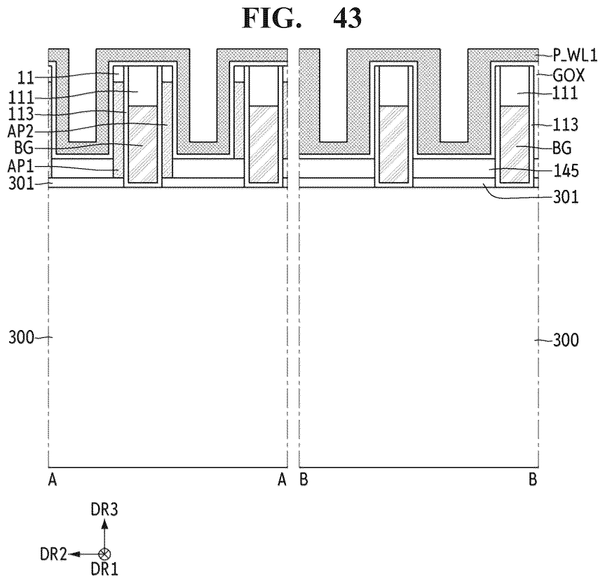

Referring to FIGS. 43 to 46, a second pre-word line pattern P_WL2 may be formed on the gate shielding pattern 145 by etching the first pre-word line pattern P_WL1.

For example, the second pre-word line pattern P_WL2 may be formed by performing anisotropic etching of the first pre-word line pattern P_WL1.

Subsequently, the vertical gate isolation pattern 144 may be formed on the gate shielding pattern 145. The vertical gate isolation pattern 144 may be formed on the second pre-word line pattern P_WL2. The vertical gate isolation pattern 144 may fill the word line trench WL_T.

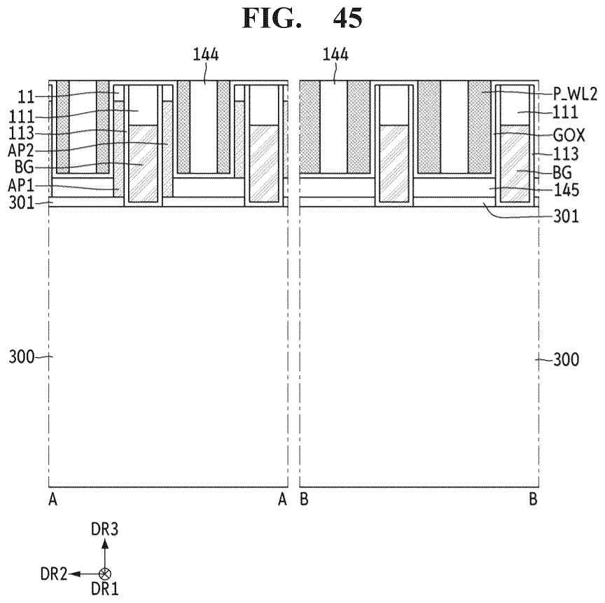

Referring to FIGS. 45 to 48, the first word line WL1 and the second word line WL2 may be formed by removing a part of the second pre-word line pattern P_WL2.

The horizontal gate isolation pattern 143 may be formed in a space formed by removing a part of the second pre-word line pattern P_WL2. Through this, the gate isolation pattern GSS including the horizontal gate isolation pattern 143 and the vertical gate isolation pattern 144 may be formed.

While the gate isolation pattern GSS is formed, the gate insulating pattern GOX that is formed on the upper surface of the back gate isolation pattern 111 may be removed. Additionally, while the gate isolation pattern GSS is formed, the lower mask film 11 may be removed, so that the first active pattern AP1 and the second active pattern AP2 may be exposed.

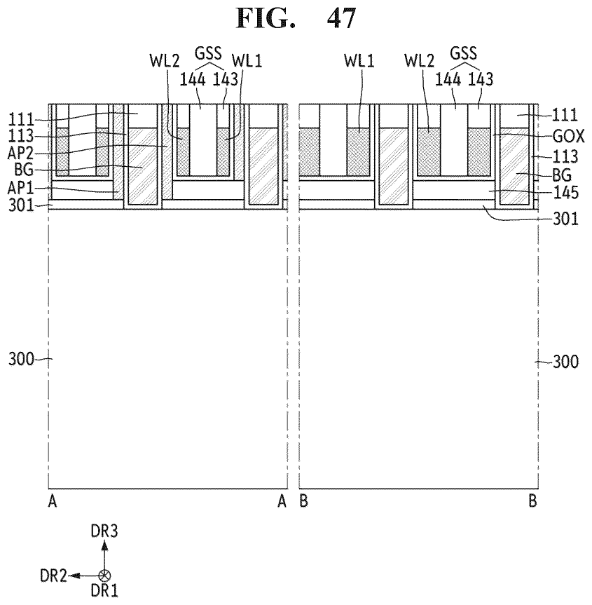

Referring to FIGS. 47 to 50, an active pattern recess AP_R may be formed by removing a part of the first active pattern AP1 and a part of the second active pattern AP2.

The active pattern recess AP_R may be formed between the back gate isolation pattern 111 and the gate isolation pattern GSS.

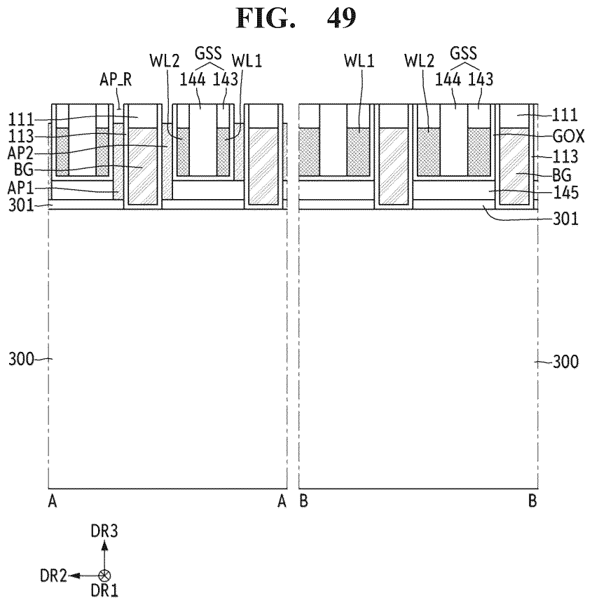

Referring to FIGS. 49 to 52, the contact pattern BC and the landing pad LP may be formed in the active pattern recess AP_R.

For example, the contact pattern BC may be formed on the first active pattern AP1 and the second active pattern AP2. The contact pattern BC may fill a part of the active pattern recess AP_R. Subsequently, the landing pad LP may be formed on the contact pattern BC. For example, the landing pad LP may fill a remainder of the active pattern recess AP_R.

In an embodiment of the present inventive concept, an impurity element may be doped into the first active pattern AP1 and the second active pattern AP2 exposed by the active pattern recess AP_R. Subsequently, the landing pad LP may be formed in the active pattern recess AP_R.

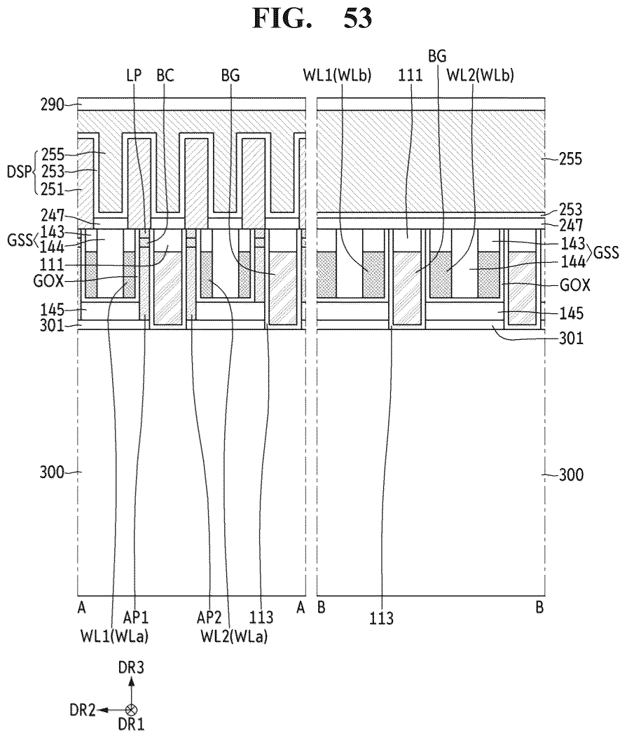

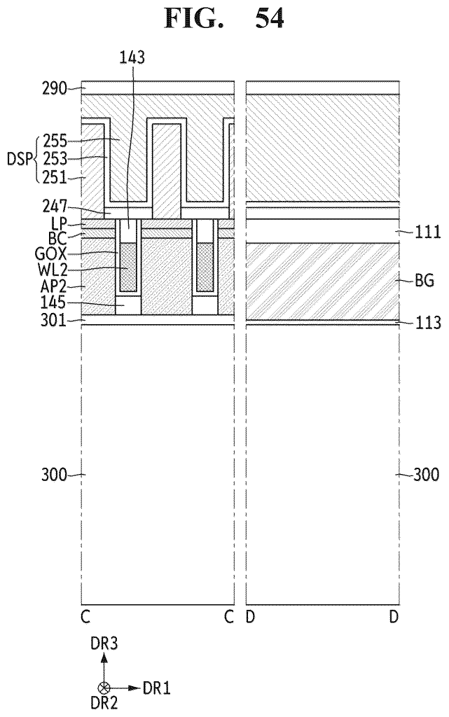

Referring to FIGS. 53 and 54, the etch stop film 247 may be formed on the landing pad LP, the gate isolation pattern GSS, and the back gate isolation pattern 111.

The storage electrode 251 may be formed on the landing pad LP by penetrating the etch stop film 247. The capacitor dielectric film 253 and the plate electrode 255 may be formed on the storage electrode 251. Through this process, the data storage patterns DSP may be formed on the landing pads LP. The data storage patterns DSP may be connected to the first active pattern AP1 and the second active pattern AP2.

Subsequently, the upper insulating film 290 may be formed on the data storage pattern DSP.

Referring to FIGS. 53 to 56, the first sub-substrate 300, on which the back gate electrodes BG, the first and second word lines WL1 and WL2, the first and second active patterns AP1 and AP2, and the data storage patterns DSP are formed, may be bonded to a second sub-substrate 400.

The back gate electrodes BG, the first and second word lines WL1 and WL2, the first and second active patterns AP1 and AP2, and the data storage patterns DSP may be disposed between the first sub-substrate 300 and the second sub-substrate 400.

In an embodiment of the present inventive concept, the first sub-substrate 300 and the second sub-substrate 400 may be bonded using a bonding adhesive film.

As an example, the second sub-substrate 400 may be a semiconductor substrate. As another example, the second sub-substrate 400 may be an insulating substrate including an insulating material.

Then, after bonding the first sub-substrate 300 to the second sub-substrate 400, a backside lapping process of removing the first sub-substrate 300 may be performed.

Removing the first sub-substrate 300 may include exposing the buried insulating layer 301 and the back gate insulating pattern 113 by sequentially performing a grinding process and a wet etching process.

Subsequently, the first active pattern AP1 and the second active pattern AP2 may be exposed by removing the buried insulating layer 301. As the buried insulating layer 301 is removed, a part of the back gate insulating pattern 113 may be exposed.

Subsequently, the exposed back gate insulating pattern 113 may be removed. Through this process, the back gate electrode BG may be exposed.

Then, a part of the back gate electrode BG may be removed by performing an etch-back process. The back gate capping pattern 115 may be formed on the recessed back gate electrode BG.

Next, the bit line BL extending in the second direction DR2 may be formed on the first active pattern AP1 and the second active pattern AP2. The shielding conductive pattern SL may be formed on the bit line BL. The shielding insulating capping film 175 may be formed on the shielding conductive pattern SL.

Subsequently, the first cell lower insulating film 271 may be formed on the shielding insulating capping film 175. The second cell lower insulating film 272 may be formed on the first cell lower insulating film 271. The first cell connection line 281 may be formed in the second cell lower insulating film 272. The third cell lower insulating film 273 may be formed on the second cell lower insulating film 272. The upper pad plug 245 and the upper bonding pad BP2 may be formed in the third cell lower insulating film 273.

Subsequently, referring to FIGS. 14 and 15, the substrate 100 in which the first peri-gate structure PG1, the first peri-connection structure 242a and 242b, the second peri-connection structure 243a and 243b, the lower bonding pad BP1, and the lower pad plug 244 are formed may be bonded to the second sub-substrate 400.

The second sub-substrate 400 and the substrate 100 may be bonded using the bonding adhesive film 267. In an embodiment of the present inventive concept, the second sub-substrate 400 and the substrate 100 may be bonded without the bonding adhesive film 267.

Then, the second sub-substrate 400 may be removed.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor memory device comprising:
a bit line extending in a first direction on a substrate;
an active pattern disposed on the bit line, and comprising a first sidewall and a second sidewall opposite to each other in the first direction, and a first surface and a second surface opposite to each other in a vertical direction that intersects the first direction, wherein the first surface of the active pattern is connected to the bit line;
a word line disposed on the first sidewall of the active pattern, and extending in a second direction crossing the first direction;
a back gate electrode disposed on the second sidewall of the active pattern, and extending in the second direction;
a data storage pattern disposed on the active pattern;
a gate isolation pattern disposed between the bit line and the data storage pattern, and disposed on the word line;
a back gate isolation pattern disposed between the back gate electrode and the data storage pattern, and disposed on the back gate electrode; and
a landing pad disposed between the gate isolation pattern and the back gate isolation pattern, and in contact with the data storage pattern.

2. The semiconductor memory device of claim 1, wherein the gate isolation pattern comprises an upper surface facing the data storage pattern, and
the landing pad does not overlap the upper surface of the gate isolation pattern in the vertical direction.

3. The semiconductor memory device of claim 2, wherein the landing pad comprises an upper surface in contact with the data storage pattern, and
the upper surface of the landing pad is substantially coplanar with the upper surface of the gate isolation pattern.

4. The semiconductor memory device of claim 2, wherein the bit line comprises an upper surface and a lower surface opposite to each other in the vertical direction,
the upper surface of the bit line faces the active pattern, and
a height that is from the upper surface of the bit line to the upper surface of the gate isolation pattern is greater than a height that is from the upper surface of the bit line to the second surface of the active pattern.

5. The semiconductor memory device of claim 1, wherein a width of the active pattern in the second direction is equal to a width of the landing pad in the second direction.

6. The semiconductor memory device of claim 1, further comprising a contact pattern disposed between the active pattern and the landing pad.

7. The semiconductor memory device of claim 1, further comprising a gate insulating pattern disposed between the word line and the active pattern,
wherein a part of the gate insulating pattern protrudes toward the data storage pattern and extends closer to the data storage pattern than the second surface of the active pattern.

8. The semiconductor memory device of claim 1, further comprising a gate insulating pattern disposed between the word line and the active pattern,
wherein the word line comprises a first surface and a second surface opposite to each other in the vertical direction,
the first surface of the word line faces the bit line, and
the gate insulating pattern extends along the first surface of the word line.

9. The semiconductor memory device of claim 1, wherein the active pattern is made of a single crystal semiconductor material.

10. The semiconductor memory device of claim 1, further comprising a shielding conductive pattern disposed on the substrate,
wherein the shielding conductive pattern comprises a shielding conductive plate and a plurality of shielding conductive line patterns protruding from the shielding conductive plate,
each of the plurality of shielding conductive line patterns extends in the first direction, and
the bit line is disposed between neighboring shielding conductive line patterns of the shielding conductive line patterns.

11. The semiconductor memory device of claim 1, further comprising a shielding conductive pattern disposed adjacent to the bit line in the second direction, and extending in the first direction,
wherein the bit line comprises an upper surface and a lower surface opposite to each other in the vertical direction,
the upper surface of the bit line faces the active pattern, and
the shielding conductive pattern is not disposed on the lower surface of the bit line.

12. A semiconductor memory device comprising:
a bit line extending in a first direction on a substrate;
a back gate electrode disposed on the bit line, and extending in a second direction crossing the first direction, wherein the back gate electrode comprises a first sidewall and a second sidewall opposite to each other in the first direction, and a first surface and a second surface opposite to each other in a vertical direction, wherein the first surface of the back gate electrode faces the bit line;
a first word line disposed on the first sidewall of the back gate electrode, and extending in the second direction;
a second word line disposed on the second sidewall of the back gate electrode, and extending in the second direction;
a first active pattern disposed between the back gate electrode and the first word line;
a second active pattern disposed between the back gate electrode and the second word line;
landing pads respectively disposed on the first active pattern and the second active pattern;
data storage patterns disposed on the second surface of the back gate electrode, and respectively connected to the landing pads; and
a back gate isolation pattern disposed between the back gate electrode and the data storage patterns, and disposed on the second surface of the back gate electrode,
wherein each of the landing pads comprises an upper surface facing the data storage patterns,
the back gate isolation pattern comprises an upper surface facing the data storage patterns, and
the upper surface of each of the landing pads is coplanar with the upper surface of the back gate isolation pattern.

13. The semiconductor memory device of claim 12, further comprising a back gate insulating pattern extending along the first sidewall of the back gate electrode and the second sidewall of the back gate electrode,
wherein the back gate insulating pattern extends to a level at which the upper surface of the landing pad is positioned.

14. The semiconductor memory device of claim 12, wherein a width of the landing pad, which is connected to the first active pattern, in the second direction is equal to a width of the first active pattern in the second direction.

15. The semiconductor memory device of claim 12, further comprising a shielding conductive pattern disposed on the substrate,
wherein the shielding conductive pattern comprises a shielding conductive plate and a plurality of shielding conductive line patterns protruding from the shielding conductive plate,
each of the plurality of shielding conductive line patterns extends in the first direction, and
the bit line is disposed between neighboring shielding conductive line patterns of the shielding conductive line patterns.

16. The semiconductor memory device of claim 12, further comprising an etch stop film extending along the upper surface of each of the landing pads and the upper surface of the back gate isolation pattern,
wherein the etch stop film is in contact with the back gate isolation pattern, and
each of the data storage patterns comprises a storage electrode penetrating the etch stop film.

17. A semiconductor memory device comprising:
a bit line extending in a first direction on a substrate;
a shielding conductive pattern disposed on the substrate, and comprising a plurality of shielding conductive line patterns adjacent to the bit line and extending in the first direction;
a back gate electrode disposed on the bit line and the shielding conductive pattern, and extending in a second direction;
a word line disposed on the bit line and the shielding conductive pattern, and spaced apart from the back gate electrode in the first direction, wherein the word line extends in the second direction;
a data storage pattern disposed on the word line and the back gate electrode;
an active pattern disposed between the bit line and the data storage pattern, and connected to the bit line and the data storage pattern, wherein the active pattern comprises a sidewall extending in a vertical direction;
a landing pad disposed between the active pattern and the data storage pattern, and comprising a sidewall extending in the vertical direction; and
a gate insulating pattern disposed between the word line and the active pattern, and extending along the sidewall of the active pattern and the sidewall of the landing pad.

18. The semiconductor memory device of claim 17, further comprising a back gate isolation pattern disposed between the back gate electrode and the data storage pattern,
wherein each of the back gate isolation pattern and the landing pad comprises an upper surface facing the data storage pattern, and
the upper surface of the landing pad is coplanar with the upper surface of the back gate isolation pattern.

19. The semiconductor memory device of claim 17, further comprising a peri-gate structure disposed between the substrate and the bit line.

20. The semiconductor memory device of claim 17, further comprising a peri-gate structure disposed on the substrate,
wherein the bit line and the data storage pattern are disposed between the substrate and the peri-gate structure.
